(19) United States
(12) Patent Application Publication
(10) Pub. No.: US 2008/0080598 A1
(43) Pub. Date: Apr. 3, 2008

(54) Method and apparatus for processing communication using different modulation schemes

(76) Inventors: Shaomin Samuel Mo, Monmouth Junction, NJ (US); Nan Guo, Cookeville, NJ (US); Robert Caiming Qiu, Cookeville, NJ (US); Kazuaki Takahashi, Osaka (JP); Suguru Fujita, Osaka (JP)

Correspondence Address: RATNERPRESTIA, P.O. BOX 980, VALLEY FORGE, PA, 19482, US

(21) Appl. No.: 11/707,530

(22) Filed: Feb. 16, 2007

Related U.S. Application Data
(60) Provisional application No. 60/848,327, filed on Sep. 29, 2006.

(51) Int. Cl. H04B 1/38; H03D 1/00; H04J 11/00

(52) U.S. Cl. 375/219; 370/203; 370/210; 375/340

(57) ABSTRACT

A transmitter and method for processing a digital data stream is disclosed. The transmitter includes a mode controller that selects one of a first mode or a second mode such that the transmitter operates with a first modulation scheme in the first mode and a second modulation scheme in the second mode. A receiver and method for processing a modulated carrier is further disclosed. The receiver also includes a mode controller such that the receiver operates with a first modulation scheme in a first mode and a second modulation scheme in a second mode. Common functions/modules of the transmitter and receiver are used in both the first and second modes.

### CROSS REFERENCE TO RELATED APPLICATIONS

This application claims the benefit of the filing date of Provisional Application Ser. No. 60/848,327 entitled INTEROPERABILITY BETWEEN AN OFDM TRANSCEIVER AND AN OOK TRANSCEIVER filed Sep. 29, 2006, the contents of which are incorporated herein by reference.

### FIELD OF THE INVENTION

The invention relates to communications systems, generally and, more particularly, to a method and apparatus for processing communications using different modulation schemes.

### BACKGROUND OF THE INVENTION

In the United States, 7 GHz of spectrum between 57 to 64 GHz are reserved for unlicensed wireless communications. As a result, 60 GHz millimeter-wave (mmwave) based technology has received increased attention.

One opportunity for this particular spectrum includes high data rate wireless personal area networks (WPAN) applications based on mmWave technology.

mmWave radio may be used in numerous WPAN applications in residential areas, offices, conference rooms, corridors and libraries, and is a candidate for in-home applications such as audio/video transmission, desktop connection, and support of portable devices including high definition video streaming, fast file transfer, and wireless Gigabit Ethernet applications.

Some low-end devices may favor modulation schemes, such as On-Off Keying (OOK), for reduced cost and reduced power consumption consideration. Some high-end devices may choose modulation schemes with better frequency efficiency, such as Orthogonal Frequency Division Multiplexing (OFDM), for data rate and performance advantage.

### SUMMARY OF THE INVENTION

The present invention is embodied in a transmitter and method for transmitting a digital data stream. The transmitter includes a transformation module that applies an inverse FFT transform to the digital data stream. The transformation module outputs an IFFT transformed data stream. The transmitter also includes a mode switch that selects one of a first mode or a second mode and a signal processor. The signal processor receives one of the digital data stream or the outputted IFFT transformed data stream according to the selected mode, processes the received data stream and outputs an analog, filtered version of the received data stream. The transmitter further includes a modulator that receives the outputted analog, filtered version of the received data stream and modulates it with a carrier.

The present invention is embodied in a transmitter and method for transmitting a digital data stream. The transmitter includes a sync unit that inserts a predetermined bit pattern into the digital data stream to form a sync data stream. Logic levels of the predetermined bit pattern are mapped to first and second signal levels such that the absolute values of the first and second signal levels are different. The predetermined bit pattern indicates a type of modulation used to modulate the digital data stream. The transmitter also includes a processing unit that processes the sync data stream to generate a first processed data stream or a second processed data stream and a modulator that receives at least one of the first processed data stream or second processed data stream and modulates one of the first processed data stream or the second processed data stream with a carrier. The first processed data stream or the second processed data stream is selected for modulation with the carrier in accordance with the type of modulation indicated by the inserted, predetermined bit pattern.

The present invention is embodied in a receiver and method for processing a modulated carrier. The receiver includes a demodulator that receives the modulated carrier, demodulates the modulated carrier and outputs an analog data stream. The receiver also includes a signal processor that processes the analog data stream and outputs a filtered, digital version of the analog data stream and a transformation module that applies an FFT transform to the filtered, digital data version to generate an FFT transformed data stream. The receiver also includes a mode controller that selects a first mode or a second mode. The receiver outputs the filtered, digital version of the analog data stream or the FFT transformed data stream according to the selected mode.

The present invention is embodied in a receiver and method for processing a modulated carrier. The receiver includes a demodulator that demodulates the modulated carrier. The receiver also includes a processing unit that processes the modulated carrier to generate at least one of a first processed data stream or a second processed data stream. The first data stream is processed according to a first type of modulation and the second data stream is processed according to a second type of modulation. The receiver further includes a modulation type detector that detects predetermined bit patterns in the first or second processed data stream regardless of whether the predetermined bit patterns had been modulated using the first type of modulation or the second type of modulation. The sequence of bits in each predetermined bit pattern indicates a type of modulation that had been used to modulate the predetermined bit pattern. The receiver additionally includes a mode controller that selects the first processed data stream or the second processed data stream in accordance a respective predetermined bit pattern detected by the modulation type detector.

### BRIEF DESCRIPTION OF THE DRAWINGS

The invention is best understood from the following detailed description when read in connection with the accompanying drawings. It is emphasized that, according to common practice, various features/elements of the drawings may not be drawn to scale. Moreover in the drawings, common numerical references are used to represent like features/elements. Included in the drawing are the following figures:

FIG. 1 is a block diagram illustrating a generalized On-Off key (OOK) transmitter 100;

FIG. 2 is a block diagram illustrating a generalized OOK receiver 200;

FIG. 3 is a block diagram illustrating a generalized Orthogonal Frequency Division Multiplexing (OFDM) transmitter 300;

FIG. 4 is a block diagram illustrating a generalized an OFDM receiver 400;

FIG. 5 is a blocked diagram of an OOK transmitter 500 illustrating certain modules/functions which affect interoperability with other modulation schemes such as an OFDM modulation scheme;

FIG. 6 is a block diagram of an OOK receiver 600 illustrating modules/functions which affect interoperability with other modulation schemes;

FIG. 7 is a block diagram of an OFDM transmitter 700 illustrating certain modules/functions which affect interoperability with other modulation schemes;

FIG. 8 is a block diagram of an OFDM receiver 800 illustrating certain modules/functions which affect interoperability with other modulation schemes;

FIG. 9 is a block diagram illustrating an OFDM/OOK transmitter 900 in accordance with an exemplary embodiment of the invention;

FIG. 10 is a block diagram illustrating an OFDM/OOK receiver 1000 in accordance with another exemplary embodiment of the invention;

FIGS. 11A-11B are timing diagrams illustrating in-phase and quadrature components of an OFDM symbol in the OFDM transmitter 700 modeled at point (b);

FIG. 11C is a graph illustrating a frequency response of the OFDM symbol in the OFDM transmitter 700 modeled at point (b);

FIGS. 12A-12B are timing diagrams illustrating in-phase and quadrature components of the OFDM symbol in the OFDM transmitter 700 modeled at point (c);

FIG. 12C is a graph illustrating a frequency response of the OFDM symbol in the OFDM transmitter 700 modeled at point (c);

FIGS. 13A and 13B are timing diagrams illustrating in-phase and quadrature components of the OFDM symbol in the OFDM transmitter 700 modeled at point (d);

FIG. 13C is a graph illustrating a frequency response of the OFDM symbol in the OFDM transmitter 700 modeled at point (d);

FIG. 14A is a timing diagram illustrating the OFDM symbol in the OFDM transmitter 700 modeled at point (e);

FIG. 14B is a graph illustrating a frequency response of the OFDM symbol in the OFDM transmitter 700 modeled at point (e);

FIGS. 15A-15B are timing diagrams illustrating in-phase and quadrature components of an OFDM symbol in the OFDM/OOK receiver 1000 modeled at point (f);

FIG. 15C is a graph illustrating a frequency response of the OFDM symbol in the OFDM/OOK receiver 1000 modeled at point (f);

FIGS. 16A and 16B are timing diagrams illustrating in-phase and quadrature components of the OFDM symbol in the OFDM/OOK receiver 1000 modeled at point (g);

FIG. 16C a graph illustrating the frequency response of the OFDM symbol in OFDM/OOK receiver 1000 modeled at point (g);

FIGS. 17A-17B are timing diagrams illustrating in-phase and quadrature components of the OFDM symbol in the OFDM/OOK receiver 1000 modeled at point (h);

FIG. 17C is a graph illustrating a frequency response of the OFDM symbol in the OFDM/OOK receiver 1000 modeled at point (h);

FIG. 18 is a graph illustrating a constellation modeled at point (i) of OFDM/OOK receiver 1000;

FIG. 19 is a block diagram illustrating an OOK transmitter 1900;

FIG. 20 is a block diagram illustrating an OFDM/OOK receiver 2000 in accordance with yet another embodiment of the invention;

FIGS. 21A-21B are timing diagrams illustrating signals in the OOK transmitter 1900 modeled at points (a) and (b);

FIG. 21C is a graph illustrating a frequency response of the signal in OOK transmitter 1900 modeled at point (b);

FIG. 22A is a timing diagram illustrating a signal in the OOK transmitter 1900 modeled at point (c);

FIG. 22B is a graph illustrating a frequency response of the signal in the OOK transmitter 1900 modeled at point (c);

FIG. 23A is a timing diagram illustrating an OOK modulated signal in OOK transmitter 1900 modeled at point (d);

FIG. 23B is a graph illustrating a frequency response of the OOK modulated signal in OOK transmitter 1900 modeled at point (d);

FIG. 24A is a timing diagram illustrating a signal in the OFDM/OOK receiver 2000 modeled at point (f);

FIG. 24B is a graph illustrating the frequency response of the signal of FIG. 24A;

FIG. 25A is a timing diagram illustrating a signal in the OFDM/OOK receiver 2000 modeled at point (g);

FIG. 25B is a graph illustrating a frequency response of the signal in OFDM/OOK receiver 2000 modeled at point (g);

FIG. 26 is a timing diagram illustrating the signal in the OFDM/OOK receiver 2000 modeled at point (h);

FIG. 27 is a block diagram illustrating an OFDM/OOK transmitter 2700 in accordance with yet another exemplary embodiment of the invention;

FIG. 28 is a block diagram illustrating an OOK receiver 2800;

FIG. 29A is a timing diagram illustrating a signal of the OOK receiver 2800 modeled at point (f);

FIG. 29B is a graph illustrating a frequency response of the signal in OOK receiver 2800 modeled at point (f);

FIG. 30A is a timing diagram illustrating the signal in the OOK receiver 2800 modeled at point (g);

FIG. 30B is a graph illustrating a frequency response of the signal in the OOK receiver 2800 modeled at point (g);

FIG. 31 is a timing diagram illustrating the signal in the OOK receiver 2800 modeled at point (h);

FIGS. 32A and 32B are a timing diagram and a graph illustrating time and frequency responses for a predetermined pattern generated by an OOK transmitter;

FIGS. 33A and 33B are a timing diagram and a graph illustrating time and frequency responses for another predetermined pattern generated by an OOK transmitter;

FIG. 34A is a timing diagram illustrating source data (pattern 1) input to OFDM transmitter 700;

FIG. 34B is a timing diagram illustrating a signal in the OFDM transmitter 700 modeled at point (d) when the source data (pattern 1) is modulated using Binary Phase Shift Keying (BPSK);

FIG. 34C is a timing diagram illustrating the signal in the signal in the OFDM transmitter 700 modeled at point (e) when the source data (pattern 1) is modulated using BPSK;

FIG. 35A is a timing diagram illustrating source data (pattern 2) input to OFDM transmitter 700;

FIG. 35B is a timing diagram illustrating a signal in the OFDM transmitter 700 modeled at point (d) when the source data (pattern 2) of FIG. 35A is modulated using BPSK;

FIG. 35C is a timing diagram illustrating the signal in the signal in the OFDM transmitter 700 modeled at point (e) when the source data (pattern 2) of FIG. 35A is modulated using BPSK;

FIG. 36A is a timing diagram illustrating the use of an unbalanced DC mapping according to yet another exemplary embodiment of the invention;

FIG. 36B is a timing diagram illustrating a signal in the OFDM transmitter 700 modeled at point (d) when the source data (pattern 2) of FIG. 36A is modulated using BPSK.

FIG. 36C is a timing diagram illustrating the signal in the OFDM transmitter 700 modeled at point (e) when the source data (pattern 2) of FIG. 36A is modulated using BPSK;

FIG. 37 is a block diagram illustrating a modulation type controller in accordance with yet another exemplary embodiment of the invention;

FIG. 38 is a block diagram illustrating a modulation type detector in accordance with yet another exemplary embodiment of the invention;

FIG. 39 is a flow chart illustrating a method of processing a digital data stream in accordance with yet another exemplary embodiment of the invention;

FIG. 40 is a flow chart illustrating a method of processing a modulated carrier signal in accordance with yet another exemplary embodiment of the invention;

FIG. 41 is a flow chart illustrating a method of processing a digital data stream in accordance with yet another exemplary embodiment of the invention; and

FIG. 42 is a flow chart illustrating a method of processing a modulated carrier signal in accordance with yet another exemplary embodiment of the invention.

### DETAILED DESCRIPTION OF THE INVENTION

Because low-end and high-end devices may use different modulation schemes, they man not be able to communicate. Low-end devices and high-end devices, however, may need to communicate with each other.

What is need is a scheme for interoperability between the modulation schemes used by these devices.

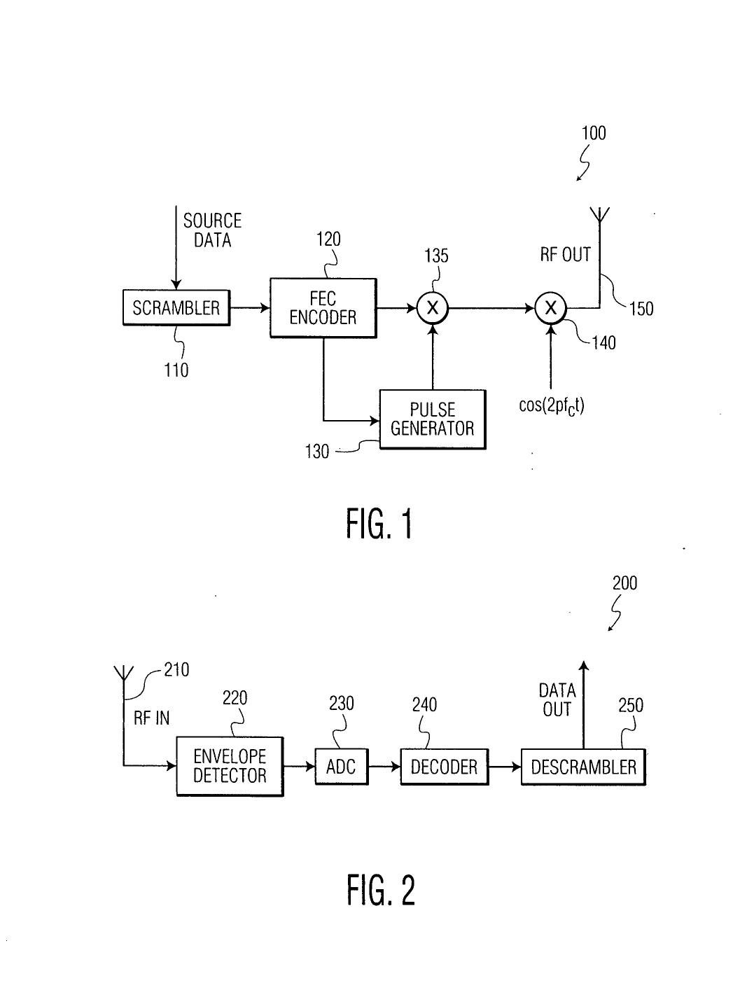

FIG. 1 is a block diagram illustrating a generalized On-Off key (OOK) transmitter 100.

Referring to FIG. 1, an OOK transmitter 100 may include a scrambler 110, a Forward Error Correction (FEC) encoder 120, a pulse generator 130, a multiplexer 135, a modulator 140 and an antenna 150. A source (not shown) may provide source data, as an input to scrambler 100. The data source may be, for example, information in the form of a bit stream to be transmitted. The scrambler 110 may be configured to scramble the source data. The scrambler 110 may scramble all of the source data or may scramble one or more portions of the source data. For example, the scrambler 110 may scramble all of the source data except repetitive data such as synchronization information. The scrambler 110 outputs the scrambled source data to the FEC encoder 120.

In certain exemplary embodiments, the scrambler 110 may scramble the source data according to a pseudo-random algorithm.

The FEC encoder 120 may process the scrambled source data and may add FEC encoding bits (e.g., error correction information) to allow for forward error correction after decoding at a receiver. That is, the FEC encoder 120 may encode the scrambled source data for use in later error correction.

Pulse generator 130, coupled to the output of FEC encoder 120, may be controlled by the encoded source data to generate pulses corresponding to the logic level (i.e., ‘1’ or ‘0’) of the encoded source data. That is, pulses generated by pulse generator 130 are multiplexed with the encoded source data at multiplexer 135 to form a pulse stream corresponding to the sequence of logic levels in the encoded source data. The output of multiplexer 135 is input to modulator 140 to up-convert (modulate) the pulse stream for transmission. That is, the source data, which is processed through modulator 140, is modulated onto a carrier wave to a designed frequency band by modulator 140 and transmitted via antenna 150.

In OOK modulation, logic level ‘1’ and logic level ‘0’ may be represented by power-on or power-off, respectively. Such a system may be viewed as an impulse-based modulation system, and such impulses may be generated with, for example, about Ins duration, for data rates up to or above 1 Gbps.

Because OOK is a non-coherent modulation scheme, simple non-coherent detection schemes, such as energy detection, may be used at a receiver. Such schemes consume less power than coherent detection. OOK is an energy efficient modulation scheme. Typically in OOK modulation, one symbol consists of one bit and has a signal level of {0,1} with an average energy per bit of 0.5.

The pulse generator 130 may be used in the OOK transmitter to group encoded data into symbols. Since, however, there are only two states in an OOK transmitter, one symbol contains one bit, and symbols may be converted into OOK pulses in base-band.

FIG. 2 is a block diagram illustrating a generalized OOK receiver 200.

Referring to FIG. 2, OOK receiver 200 may include an antenna 210, an envelope detector 220, an Analog-to-Digital Converter (ADC) 230, a decoder 240 and a descrambler 250. Antenna 210 is configured to receive a modulated carrier wave, for example, received from OOK transmitter 100. Antenna 210 is coupled to envelope detector 220. Envelope detector 220 may receive the modulated carrier wave from antenna 210, may detect the envelope of the modulated carrier wave received by antenna 210 and may output the detected envelope to ADC 230. That is, envelope detector 220 may down-converter the modulated carrier wave to base-band. ADC 230 may digitally sample the detected envelope (the base-band) received from envelope detector 220 and may output a digitally sampled version of the envelope of the modulated carrier wave.

Decoder 240 may receive the digitally sampled version from the output of ADC 230 and may decode it. That is, the decoder 240 may provide an inverse operation to that of the FEC encoder 120 of the OOK transmitter 100. The descrambler 250 coupled to decoder 240 descrambles the output of decoder 240 in accordance with a descrambling algorithm (for example, a pseudo-random algorithm matched to scrambler 110 of OOK transmitter 100). That is, when OOK receiver 200 receives, for example, an incoming signal from OOK transmitter 100, inverse operations may be conducted to convert the modulated OOK signal into the original source data transmitted by OOK transmitter 100.

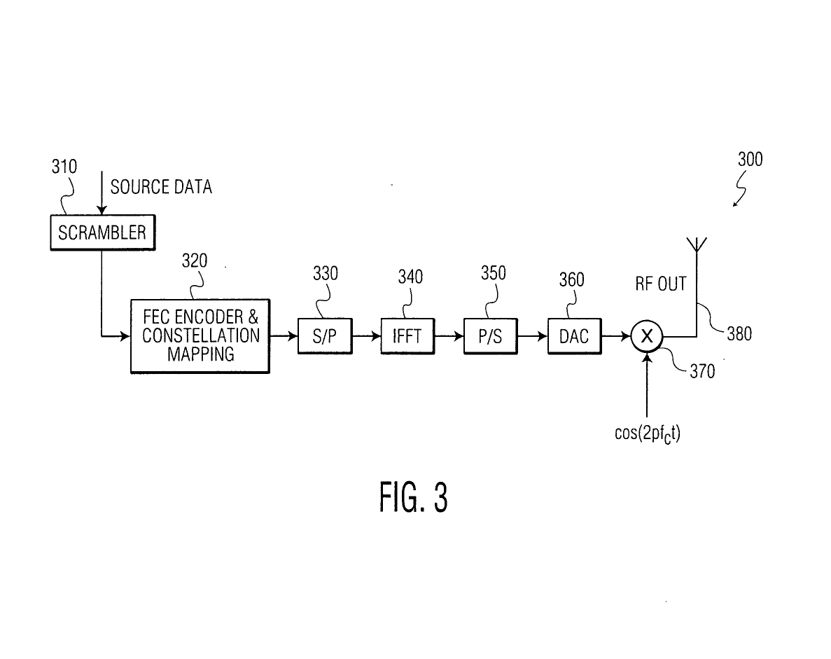

FIG. 3 is a block diagram illustrating a generalized Orthogonal Frequency Division Multiplexing (OFDM) transmitter 300.

Now referring to FIG. 3, OFDM transmitter 300 may include scrambler 310, FEC encoder and constellation mapper 320, Serial-to-Parallel Converter (S/P) 330, Inverse Fast Fourier Transform (IFFT) module 340, Parallel-to-Serial Converter (P/S) 350, Digital-to-Analog Converter (DAC) 360, modulator 370 and antenna 380. Source data, for example, a digital data stream, may be input to scrambler 310 for scrambling the source data. Scrambler 310 may be used to randomize the sequence of the transmitted data stream, for example, to avoid the presence of spectral lines in the transmitted signal.

In certain exemplary embodiments, the scrambler 310 may use a Linear Feedback Shift Register (LFSR) to implement a pseudo-random number generator. Scrambler 310 may also provide DC balance.

The output of scrambler 310 may be received by FEC encoder & constellation mapper 320 to encode the data for error correction. The encoded data may be grouped into symbols and the resulting symbols may be mapped onto a designated constellation via FEC encoder & constellation mapper 320. The output of FEC encoder & constellation mapper 320 may be received by S/P 330 and output to IFFT module 340. Thus, the symbols mapped by FEC encoder & constellation mapper 320 may be converted into OFDM symbols by IFFT module 340 using an IFFT algorithm. The OFDM symbols may be output via P/S 350 to DAC 360. DAC 360 converts the OFDM symbols to a continuous time (i.e., analog) version of the OFDM symbols, which are modulated onto a carrier wave of a designated frequency band and may be transmitted via antenna 380.

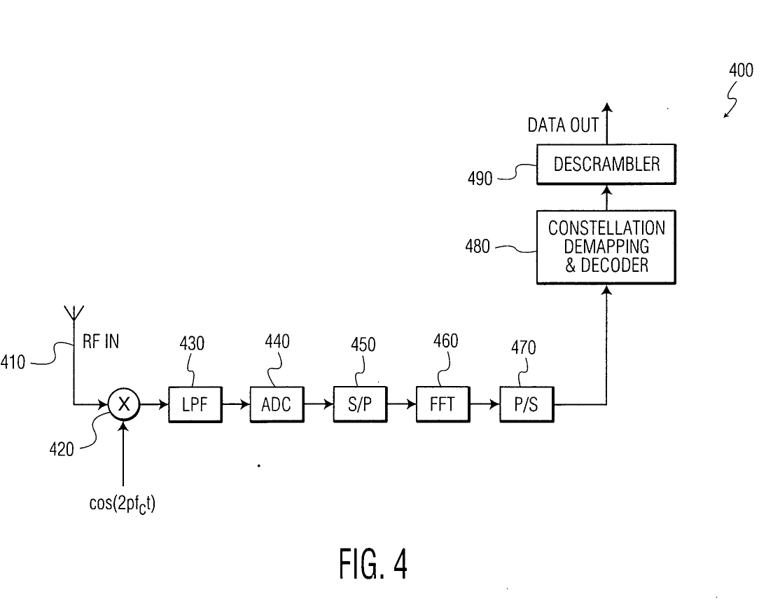

FIG. 4 is a block diagram illustrating a generalized an OFDM receiver 400.

Referring to FIG. 4, OFDM receiver 400 may include antenna 410, demodulator 420, Low Pass Filter (LPF) 430, ADC 440, S/P 450, FFT module 460, P/S 470, constellation demapper & decoder 480 and descrambler 490. When the OFDM receiver 400 receives an OFDM modulated signal, inverse operations corresponding to the operations of the OFDM transmitter 300 may be conducted to convert the modulated OFDM signal into the original source data transmitted, for example, by OFDM transmitter 300.

When antenna 410 receives a modulated carrier wave modulated with OFDM symbols, demodulator 420 which is coupled to antenna 410, may demodulate the received modulated carrier wave to produce a base-band signal. LPF 430, which is coupled to demodulator 420, may filter out the high frequency components of the base-band signal from demodulator 420 and may output a low pass filtered version (i.e., the low frequency components) of the demodulated signal to ADC 440. ADC 440 may digitally sample the low pass filtered version of the demodulated signal and may output the digitally sampled version, as OFDM symbols to S/P 450.

The FFT module 460, which is coupled to S/P 450, may receive the OFDM symbols from ADC 440 and may convert the OFDM symbols in time domain to symbols in frequency domain. Constellation demapper & decoder 480 may receive via P/S 470 coupled to FFT module 460, the converted symbols and may decode and demap the symbols to produce a scrambled version of the original source data transmitted, for example, by OFDM transmitter 300. Descrambler 490 may receive the scrambled version of the original source data and may descramble the scrambled source data to reproduce the original source data.

The inventors of the present invention have found that to enable interoperability between different modulation schemes, such as OOK modulation and OFDM modulation, that common modules with the same function in different modulation systems may be omitted for analysis purposes. That is, although certain modules/functions, (e.g., scrambler/descrambler and FEC encoder/decoder modules/functions are used in OOK systems and OFDM systems, these modulates/functions which are common to both types of systems do not affect interoperability between the systems. Further, the inventors have also found that if one bit is mapped into one symbol in OFDM transmitters and OFDM receivers, then the constellation mapping/demapping module/function may also be omitted in an analysis of interoperability between OOK modulation and OFDM modulation systems.

FIG. 5 is a blocked diagram of an OOK transmitter 500 illustrating certain modules/functions which affect interoperability with other modulation schemes such as an OFDM modulation scheme.

Referring to FIG. 5, source data, such as symbols (with one bit mapped to a respective symbol) may control the pulse generator 530 to generate pulses corresponding to the value of the source data (symbol). That is, pulses generated by pulse generator 530 may be multiplexed with, for example, these symbols to generate a pulse stream. The generation (or lack of generation) of a pulse may be in accordance with the value of a corresponding symbol in the input stream. The pulses stream may be output by multiplexer 535. For example, a pulse may be generated when the symbol value is a logic level ‘1’ while a pulse may not be generated for a symbol value of logic level ‘0’. The duration of each pulse may be equal to a symbol period. The output of multiplexer 535 may be input to modulator 540 to up-convert (modulate) the base-band pulse stream to the designated frequency band which may be transmitted via antenna 550.

In certain exemplary embodiments, logic levels ‘1’ and ‘0’ are described, one of skill in the art understands that such levels may be reversed such that, for example, a logic level ‘0’ may generate an impulse and a logic level ‘1’ may not generate an impulse.

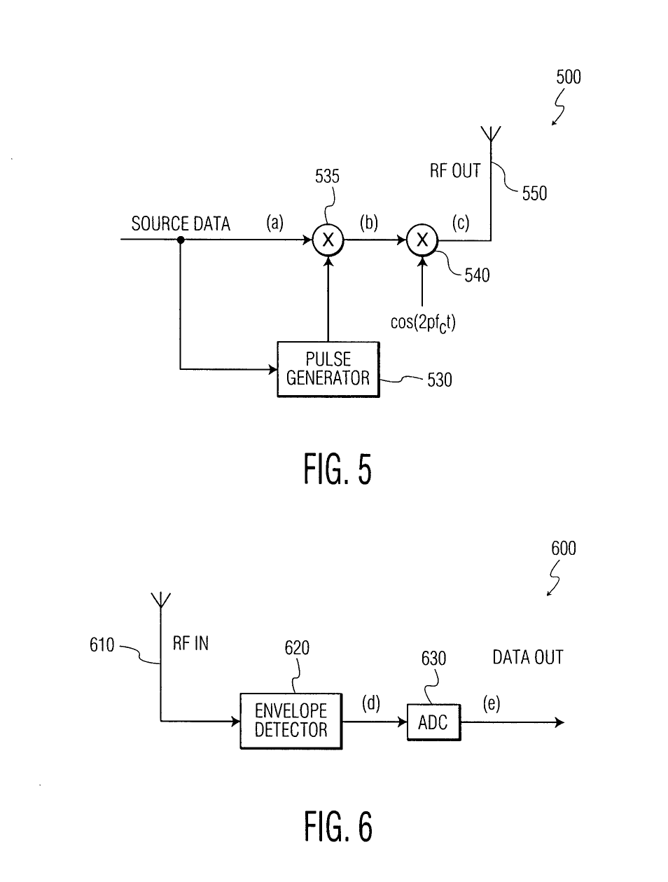

FIG. 6 is a block diagram of an OOK receiver 600 illustrating modules/functions which affect interoperability with other modulation schemes.

Referring to FIG. 6, when the OOK receiver 600 receives a modulated signal, for example, from OOK transmitter 500, envelope detector 620 may receive the modulated signal via antenna 610 and may detect to envelop of the modulated signal (e.g., the base-band signal). The output of envelope detector 620 may be received by ADC 630. The output of envelope detector 620 may be used to determine signal strength values. These values may be converted into samples by ACD 630 and provided to other base-band modules for further processing.

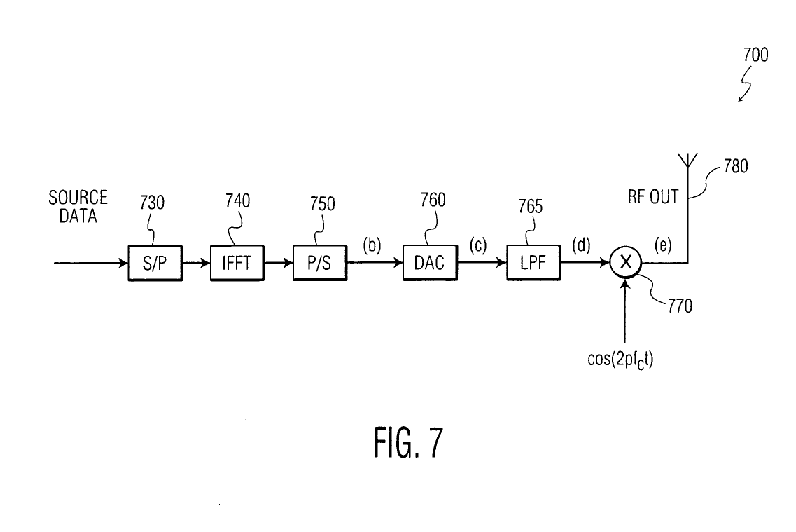

FIG. 7 is a block diagram of an OFDM transmitter 700 illustrating certain modules/functions which affect interoperability with other modulation schemes;

Now referring to FIG. 7, the OFDM transmitter 700 may include a S/P 730, an IFFT module 740, a P/S 750, a DAC 760, an LPF 765, a modulator 770 and an antenna 780. The S/P 730, the IFFT module 740, the P/S 750, and the DAC 760 may operate the same as S/P 330, IFFT module 340, P/S 350, and DAC 360, respectively.

S/P 730, IFFT 740 and P/S 750 may be used to convert symbols in frequency domain to OFDM symbols/samples in time domain. That is, in general, symbols at the input to S/P 730 may consist of different bits based on constellation mapping on each sub-carrier. For example, one symbol may consist of one bit for Binary Phase-Shift Keying (BPSK), two bits for Quadrature Phase-Shift Keying (QPSK) and four bits for 16-Quadrature Amplitude Modulation (16-QAM).

Symbols generally refer to data either before the IFFT module in a transmitter transmitting coherent signals or data after the FFT module in a receiver receiving coherent signals. Moreover, OFDM symbols generally refer to data after the IFFT module in such a transmitter or the data before the FFT module in such a receiver. Symbols are in the frequency domain while OFDM symbols are in the time domain. Further, one OFDM symbol consists of N samples. Symbols X(k) in the frequency domain may be converted into samples x(n) in the time domain via an IFFT module. Symbols in the frequency domain may also be obtained from an OFDM symbol in the time domain via an FFT module. The relationship between a symbol and samples of an OFDM symbol may be expressed as shown in equations (1) and (2):

$$\begin{matrix}x ( n ) = \frac{1}{N} {\sum }_{k = 0}^{N - 1} X ( k ) {e}^{j2π nk / N} k = 0 , 1 , … , N - 1 & ( 1 ) \\ X ( k ) = {\sum }_{n = 0}^{N - 1} x ( n ) {e}^{- j2π nk / N} n = 0 , 1 , … , N - 1 & ( 2 )\end{matrix}$$

where x(n) is a sample of an OFDM symbol in the time domain and X(k) is a symbol in the frequency domain.

One of skill in the art understands that the number of symbols input to the IFFT module is equal to the number of output samples of OFDM symbols from the IFFT module. Thus, the number of symbols at point (a) of the OFDM transmitter 700 is equal to the number of samples at point (b) of the OFDM transmitter 700. DAC 760 may hold the symbols for a certain period (i.e., the hold time) to change a discrete time signal into a continuous time signal. At point (c) of the OFDM transmitter 700 a staircase signal may be present.

The LPF 765 is coupled to DAC 760 to output at point (d) a smoothed waveform to filter out ripples in the stop band. The smoothed waveform may be received at modulator 770. The base-band signal (i.e. the smoothed waveform) may be up-converted (i.e., modulated onto) a carrier wave of a designated frequency band and may be transmitted via antenna 780. The up-conversion may be performed in accordance with the formula (3):

s(t)=mₗ(t)cos(2πf_{c}t)−m_{Q}(t)sin(2πf_{c}t) (3)

where I is the in-phase component of the signal and Q is the quadrature component of the signal at point (d), and f_{c} is the carrier frequency.

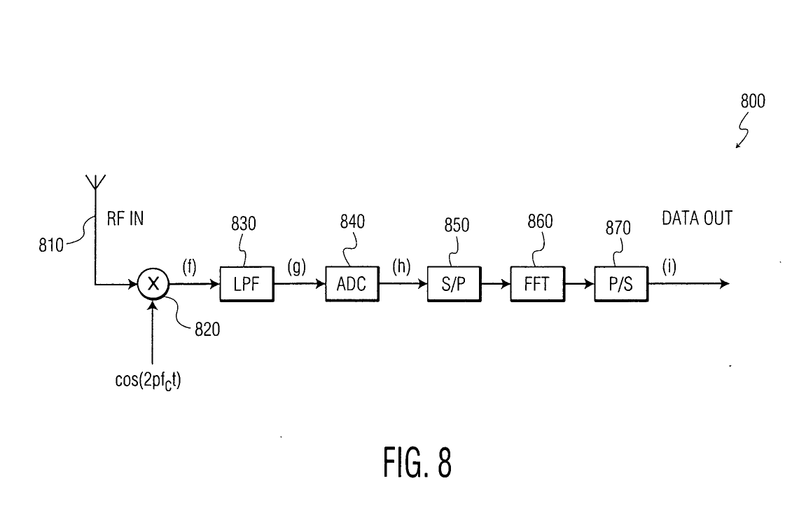

FIG. 8 is a block diagram of an OFDM receiver 800 illustrating certain modules/functions which affect interoperability with other modulation schemes.

Referring to FIG. 8, the OFDM receiver 800 may include an antenna 810, a demodulator 820, an LPF 830, an ADC 840, a S/P 850, an FFT module 860, and a P/S 870. When the signal transmitted from an OFDM transmitter reaches the OFDM receiver 800, the received signal is down-converted (i.e. demodulated to base-band) by demodulator 820 after reception by antenna 810. LPF 830 may be used to filter out high frequency components in the base-band signal such that the low frequency components of the base-band signal may be output to ADC 840. ADC 840 may digitally sample the analog (continuous-time) base-band signal from LPF 830 and may convert the continuous-time signal into a discrete time signal such that the signal at point (h) becomes OFDM samples. These OFDM samples are similar to the signal at point (b) of OFDM transmitter 700. The OFDM samples may be received by FFT module 860 via S/P 850 and may be converted to symbols in the frequency domain by FFT module 860 at point (i). That is, the output of FFT 860 may be transmitted via P/S 870 to other components of the OFDM receiver 800. These other components, such as a constellation mapper and decoder and descrambler are not shown in FIG. 8 because they do not affect interoperability.

Although certain exemplary embodiments of the invention are described in terms of OOK modulation, it is contemplated that other non-coherent modulation schemes such as Pulse Amplitude Modulation (PAM), Amplitude Shift Keying (ASK) and Pulse Position Modulation (PPM), among others, may be interoperated with coherent modulation schemes such as BPSK, and Offset Quadrature Phase Shift Keying (OQPSK), among others. That is, for example, OFDM may be interoperated with other non-coherent modulation schemes such as PAM, ASK or PPM, among others. Moreover, OOK may be interoperated with other single-carrier modulation schemes such as BPSK, QPSK, or OQPSK, among others.

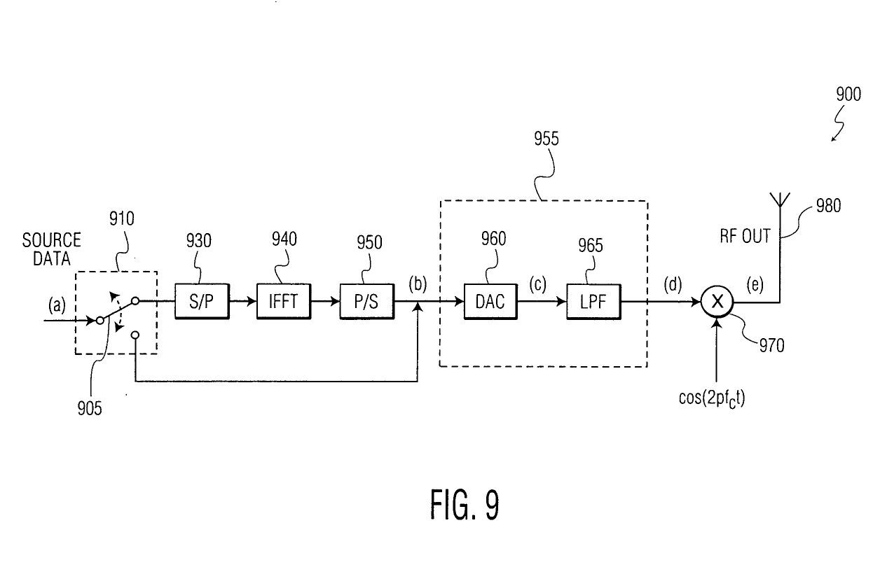

FIG. 9 is a block diagram illustrating an OFDM/OOK transmitter 900 in accordance with an exemplary embodiment of the invention. For brevity, functions/modules, such as scrambling, FEC encoding and constellation mapping, are not shown because these functions/modules do not affect interoperability between OFDM and OOK modulation schemes.

Now referring to FIG. 9, the OFDM/OOK transmitter 900 may include a mode controller 910, a S/P 930, an IFFT module 940, a P/S 950, a signal processor 955 and a modulator (i.e., up-converter) 970. A data source, which may be a bit stream, may be input to switching unit 910. The mode controller 910 may include a switching unit 905 that may include two or more switching positions such that in a first switching position the source data may be input via S/P 930 to IFFT module 940. In the first mode of operation corresponding to the first position of the switching unit 905, the source data is modulated using an OFDM modulation scheme. That is, the source data which includes symbols may be received by IFFT module 940 and may be transformed to OFDM symbols. The OFDM symbols may be output by the IFFT via P/S/950 module 940 to signal processor 955.

Signal processor 955 may include DAC 960 and LFP 965. The OFDM symbols output via P/S 950 may be selectively input to the DAC 960 of signal processor 955. The DAC 960 may convert the OFDM symbols to an analog (i.e., a continuous-time) version of the OFDM symbols, and may output it to the LPF 965. LPF 965 may remove the high frequency components of the analog version of the OFDM symbols, and may output the low frequency components of the analog version of the OFDM symbols to modulator 970. A carrier wave may be modulated with the analog version of the OFDM symbols and may be transmitted via antenna 980. In the first mode of operation, the source data may be modulated in an OFDM modulation scheme and may be transmitted via antenna 980.

When mode controller 910 controls the switching unit 905 to switch to a second position, the source data is input directly to signal processor 955. The source data, which may be a bit stream, may be converted to an analog version of the bit stream by DAC 960 and may be output to LPF 965. The LPF 965 may remove high frequency components of the analog version of the source data and may output the low frequency components of the analog version of the source data to modulator 970. A carrier wave may be modulated with the output of LPF 965 by modulator 970 and may be transmitted via antenna 980. That is, in the second mode of operation, the source data may be transmitted via antenna 970 using an OOK transmission scheme.

It is understood by one of skill in the art that in the first mode of operation, in which the source data is transmitted using an OFDM modulation scheme, each bit may be mapped to only one symbol. That is, a one-for-one relationship between symbols and bits exists. Moreover, one of skill understands that FEC encoding and/or scrambling are not addressed in FIG. 9, however, such functions/modules may be incorporated into the OFDM/OOK transmitter 900 as long as the receiver, (e.g., the OFDM/OOK receiver 1000, the OFDM receiver 400 and/or the OOK receiver 600 incorporate the inverse unit/function (i.e., FEC decoding and/or descrambling)).

In various exemplary embodiments, the receivers and transmitters are illustrated as dual mode (i.e., using OOK and OFDM modulation schemes), however, it is contemplated that any number of different modulation schemes may be incorporated into a receiver or transmitter including both coherent and non-coherent modulation schemes such as OOK, ASK, PPM, PAM, OFDM, BPSK, QPSK, 16-QAM, and OQPSK among others.

Although the switching unit 905 is illustrated as a single-pole/single throw (SPST) device, it is contemplated that the switching unit 905 may be any number of different switching devices including, for example, a double pole/double-throw (DPDT) device as long as the source data, the S/P 930, the IFFT module 940 and the P/S 950 are placed in-line with the signal processor 955 in the first mode of operation and the source data is input directly to signal processor 955 (i.e., the S/P 930, the IFFT module 940 and the P/S 950 are bypassed) in the second mode of operation. Further, any number and arrangement of switching devices may be used as long as the source data is applied alternatively to either S/P 930 or the signal processor 955 in accordance with the selected mode of operation. Selection of the mode of operation may be based on a user setting or may be selected in accordance with information in the source data or via an external source such as a controller external to the transmitter (e.g., a controller of receiver/transmitter combination (i.e., a transceiver). Since base-band processing may be implemented using a Digital Signal Processor (DSP), a Field Programmable Gate Array (FPGA) and/or an Application-Specific Integrated Circuit (ASIC), switch functions may be easily performed by a software switch command. A more detailed description of the selection process is provided below.

It is understood by one skilled in the art that in the first mode of operation, in which the source data is transmitted using an OFDM modulation scheme, each bit may be mapped to only one symbol. That is, a one-for-one relationship between symbols and bits exists. Moreover, one skilled understands that FEC encoding and/or scrambling are not addressed in FIG. 9, however, such functions/modules may be incorporated into the OFDM/OOK transmitter 900 as long as the receiver, (e.g., the OFDM/OOK receiver 1000, the OFDM receiver 400 and/or the OOK receiver 600 incorporate the inverse unit/function (i.e., FEC decoding and/or descrambling)).

The inventors have observed that OOK signals and OFDM signals have some similarities. The modulated OOK signal may be represented by a modulated impulse for a logic level ‘1’ and silence for a logic level ‘0’. The modulated OFDM signal may be represented by OFDM symbols and each OFDM symbol may consist of samples, i.e., x(n), where n=0, 1 . . . , N−1. The DAC 960 may change a sample into a pulse. The difference between OFDM samples and OOK pulses is that the OOK pulses may have only two levels while the OFDM samples may have multiple values. In other words, in one OFDM symbol time the following equations (4) and (5) hold that:

$$\begin{matrix}{w}_{OOK} ( n ) = \{ \begin{matrix}p ( t ) , & if x ( n ) = 1 \\ 0 , & if x ( n ) = 0\end{matrix} n = 0 , 1 … , N - 1 & ( 4 ) \\ {w}_{OFDM} ( n ) = {p}_{t} ( t ) , i ∈ [ 1 , M ] , n = 0 , 1 … , N - 1 & ( 5 )\end{matrix}$$

where p(t) and pᵢ(t) represent waveforms, w_{OOK}(N) and w_{OFDM}(n) denote OOK symbols and samples in an OFDM symbol, respectively, and M is a large number. Thus, if the OFDM samples represent two values, an OFDM transmitter may generate the same signal as an OOK transmitter.

When the OFDM/OOK transmitter 900 is used to generate an OOK modulated signal, the IFFT module 940 may be bypassed. Because one symbol consists of a single bit in OOK modulation, symbols at the data source (i.e. point (a) of the OFDM/OOK transmitter 900) consist of one bit. This bit may be used to directly drive DAC 960 (i.e., a logic level ‘1’ may generate an impulse and a logic level ‘0’ does not generate any impulse). Thus, the signal taken at point (b) in the OFDM/OOK transmitter 900 in the second mode of operation (i.e. using OOK modulation), is similar to the signal taken at point (b) in the OOK transmitter 500. This is because, the symbols taken at point (b) for OFDM/OOK transmitter 900 consist of a single bit and may have two states (i.e., logic level ‘1’ or logic level ‘0’). Samples of an OFDM symbol may be expressed as follows in equation (6):

$${w}_{OFDM} ( n ) = \{ \begin{matrix}p ( t ) , & if x ( n ) = 1 \\ 0 , & if x ( n ) = 0\end{matrix} n = 0 , 1 … , N - 1 \qquad ( 6 )$$

### Thus, w_{OOK}(n)=w_{OFDM}(n), if X_{OOK}(n)=X_{OFDM}(n).

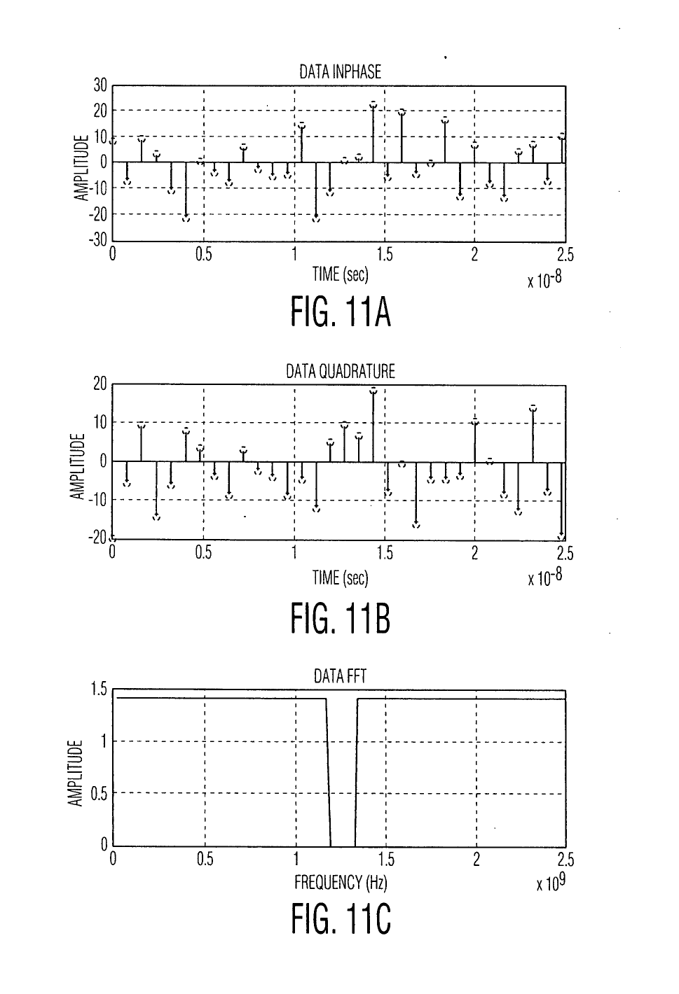

The inventors have run a simulation of a model of the operation of the OFDM/OOK transmitter 900. A description of the simulation results will be discussed with regard to FIGS. 11A-11C, 12A-12C, 13A-13C and 14A-14B.

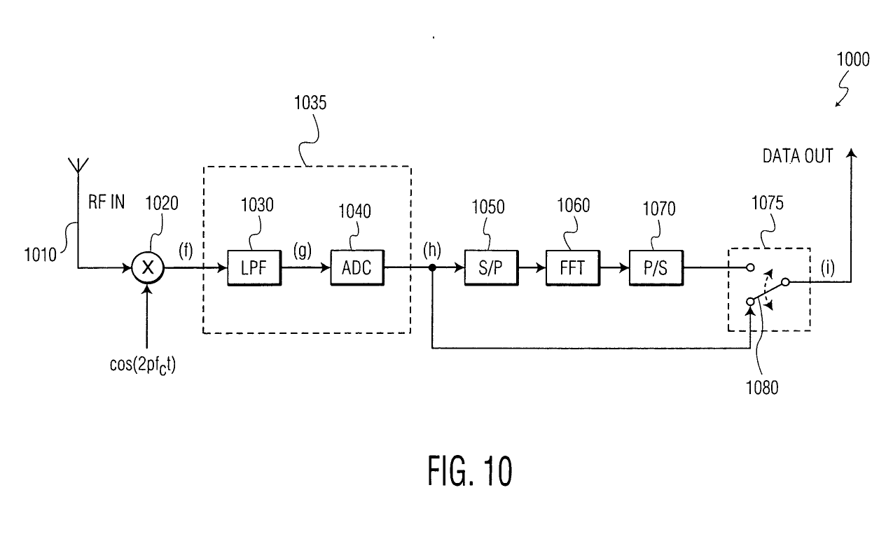

FIG. 10 is a block diagram illustrating an OFDM/OOK receiver 1000 in accordance with another exemplary embodiment of the invention. For brevity, certain functions which do not affect interoperability are not shown. Since a single bit may be mapped to one symbol in the OFDM modulation scheme, constellation mapping and demapping are also not shown. One of skilled in the art understands that this is a simplification of an OFDM modulation scheme.

Now referring to FIG. 10, the OFDM/OOK receiver 1000 may include an antenna 1010, a demodulator (i.e., down-converter) 1020, a signal processor 1035, a S/P 1050, an FFT module 1060, a P/S 1070 and a mode controller 1075. The signal processor 1035 may include an LPF 1030 and an ADC 1040. The mode controller 1075 may include a switching unit 1080.

When the OFDM/OOK receiver 1000 receives an OFDM modulated signal, such as from OFDM/OOK transmitter 900 operating in the first mode of operation, the OFDM/OOK receiver 1000 may operate in a first mode of operation. That is, mode controller 1075 may control the switching unit 1080 to be switched to a first position such that the S/P 1050, the FFT module 1060 and P/S 1070 are not bypassed (i.e., are in-line with signal processor 1035.) The OFDM modulated signal, which may be received by antenna 1010 may be demodulated by demodulator 1020 and filtered by LPF 1030 of signal processor 1035. The low frequency components of the base-band signal may be output to ADC 1040 at point (g). ADC 1040 may convert the base-band signal into OFDM symbols and output the OFDM symbols at point (h). The OFDM symbols may be input to FFT module 1060 via S/P 1050 to convert the OFDM symbols in the time domain into symbols in the frequency domain. The symbols in the frequency domain may be output via P/S 1070 and switching unit 1080 of mode controller 1075.

When OFDM/OOK receiver 1000 receives an OOK modulated signal, such as from the OFDM/OOK transmitter 900 operating in the second mode of operation, the OFDM/OOK receiver 1000 may operate in a second mode of operation. That is, switching unit 1080 may be switched by mode controller 1075 to a second position such that the S/P 1050, the FFT module 1060 and the P/S 1070 are bypassed. Thus, the OOK modulated signal may be received by antenna 1010 and outputted to demodulator 1020 to demodulate (i.e., down-convert) the OOK modulated signal to a base-band signal at point (f). The LPF 1030 may receive and filter out high frequency components of the base-band signal and may output the filtered base-band to ADC 1040 at point (g). The ADC may convert the signal into samples at point (h). The samples may bypass the S/P 1050, the FFT module 1060, and the P/S 1070 using switching unit 1080.

Although modules/functions for FEC decoding, constellation demapping and descrambling are not shown for the sake of brevity, these modules/functions are contemplated to be included in the OFDM/OOK receiver 1000.

To configure the OFDM/OOK receiver 1000 to be interoperable with both OFDM and OOK modulation schemes, symbol time (i.e., the interval period of each symbol) may be set such that it is equal to the sample time of the OFDM modulation scheme. That is, the symbol rate of the OOK modulation scheme may be the same as the sample rate of the OFDM modulation scheme. For example, in a multi-band-OFDM system, sampling frequency may be 528 MHz, therefore, the OOK sample interval may equal 1/528 MHz or 1.89 ns. Moreover, if an time interval for an OOK symbol is 800 ps, the frequency of an OFDM sample=1.25 GHz.

Although the switching unit 1075 is shown as a single-pole-throw device, any number and arrangement of switching devices are possible as long as the first and second modes of operation can be achieved.

Simulations have been conducted to model the operations of the OFDM/OOK transmitter 900 and OFDM/OOK receiver 1000. More particularly, the simulations model:

(1) an OFDM modulated signal being transmitted from the OFDM/OOK transmitter 900 and received by the OFDM/OOK receiver 1000;

(2) an OOK modulated signal being transmitted from the OOK transmitter 1900 and being received by the OFDM/OOK receiver 1000; and

(3) an OOK signal being transmitted from the OFDM/OOK transmitter 900 and received by an OOK receiver 2800.

In the simulations, interpolators and discriminators are used to simulate functions of DAC 960 and ADC 1040, respectively. For the first simulation, namely; the simulation of an OFDM modulated signal being transmitted from an OFDM/OOK transmitter 900 to an OFDM/OOK receiver 1000, the OFDM transmitter and OFDM receiver are modeled based on the block diagrams of FIGS. 7 and 8. In the simulation, one OFDM symbol time is simulated. The system parameters are as listed in Table 1. QPSK is employed on each sub-carrier as the modulation scheme.

TABLE 1

| Parameter | Description | Value |
|---|---|---|
| f_{S} | Sampling frequency | 1.25 GHz |
| N_{T} | Number of total sub-carriers (FFT size) | 128 |
| N | Number of data sub-carriers | 118 |
| N | Number of guard sub-carriers | 10 |
| Δ | Sub-carrier frequency spacing | 9.8 MHz (=f_{S}/N_{FFT}) |
| f_{C} | Carrier frequency | 60 GHz |

FIGS. 11A-11B are timing diagrams illustrating in-phase and quadrature components of an OFDM symbol in the OFDM transmitter 700 modeled at point (b) (i.e., after IFFT module 740). The signal at point (b) of OFDM transmitter 700 is a discrete time base-band signal. FIG. 11C is a graph illustrating a frequency response of the OFDM symbol in the OFDM transmitter 700 modeled at point (b). The spectrum is flat over the frequencies with data sub-carriers, but is null deeply over the frequency with guard-sub-carriers. It is understood by one skilled in the art that the simulation of OFDM/OOK transmitter 900 in the OFDM mode is the same as the OFDM transmitter 700.

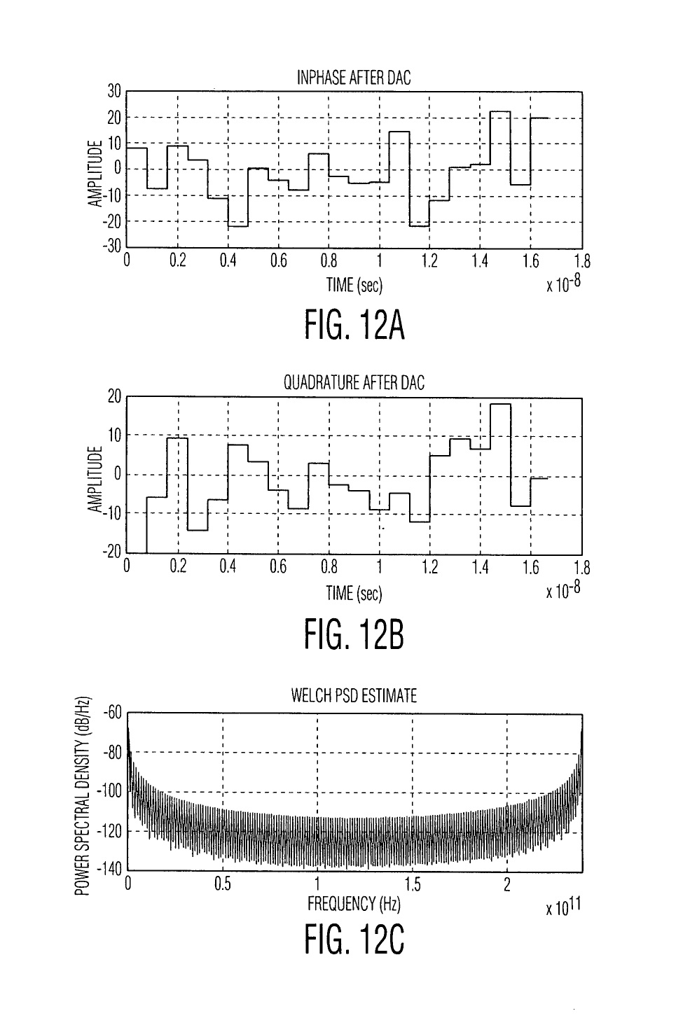

FIGS. 12A-12B are timing diagrams illustrating in-phase and quadrature components of the OFDM symbol in the OFDM transmitter 700 modeled at point (c) (i.e., after DAC 760). A continuous time base-band signal is generated modeled at point (c). FIG. 12C is a graph illustrating a frequency response of the OFDM symbol in the OFDM transmitter 700 modeled at point (c). Many ripples may appear in the stop band. The peak of the stop band ripples may be around −110 dB.

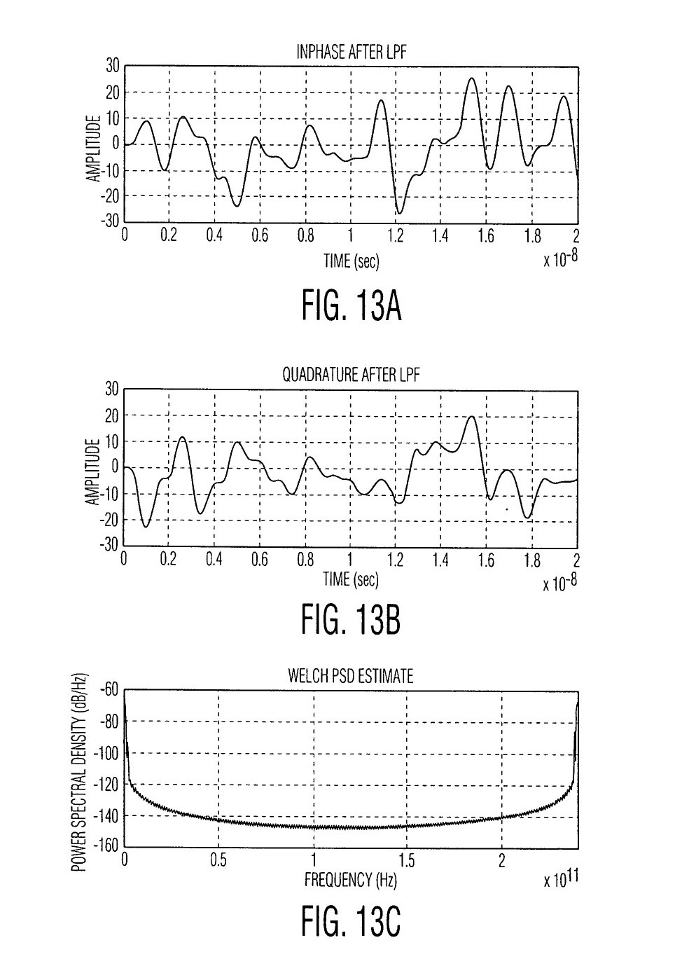

FIGS. 13A and 13B are timing diagrams illustrating in-phase and quadrature components of the OFDM symbol in the OFDM transmitter 700 modeled at point (d) (i.e., after LPF 765). FIG. 13B is a graph of the quadrature component of the samples of an OFDM of the OFDM symbol modeled at point (d) of the OFDM transmitter 700 of FIG. 7.

FIG. 13C is a graph illustrating a frequency response of the OFDM symbol in the OFDM transmitter 700 modeled at point (d) (i.e., after LPF 765). The in-phase and quadrature components of the signal modeled at point (d) may be continuous-time based-band signals. These signals may be smoothed such that the high frequency components may be filtered out by LPF 765 of OFDM transmitter 700. Ripples in the stop band may be removed by LPF 765 such that the stop band spectrum may be reduced to below about −140 dB.

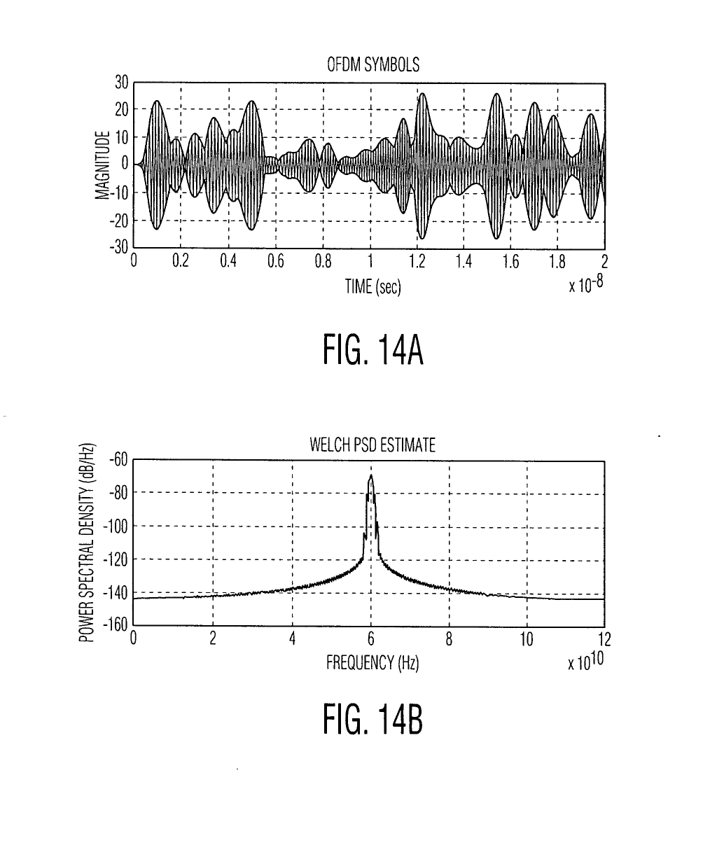

FIG. 14A is a timing diagram illustrating the OFDM symbol in the OFDM transmitter 700 modeled at point (e). That is, it is a graph of the signal after modulator 770. Modulator 770 based on, for example, the formula in equation (5) real changes a complex signal with in-phase and quadrature components into a real signal. This signal is the OFDM symbol and is a continuous time pass-band signal. FIG. 14B is a graph illustrating a frequency response of the OFDM symbol in the OFDM transmitter 700 modeled at point (e) with a center frequency of 60 GHz.

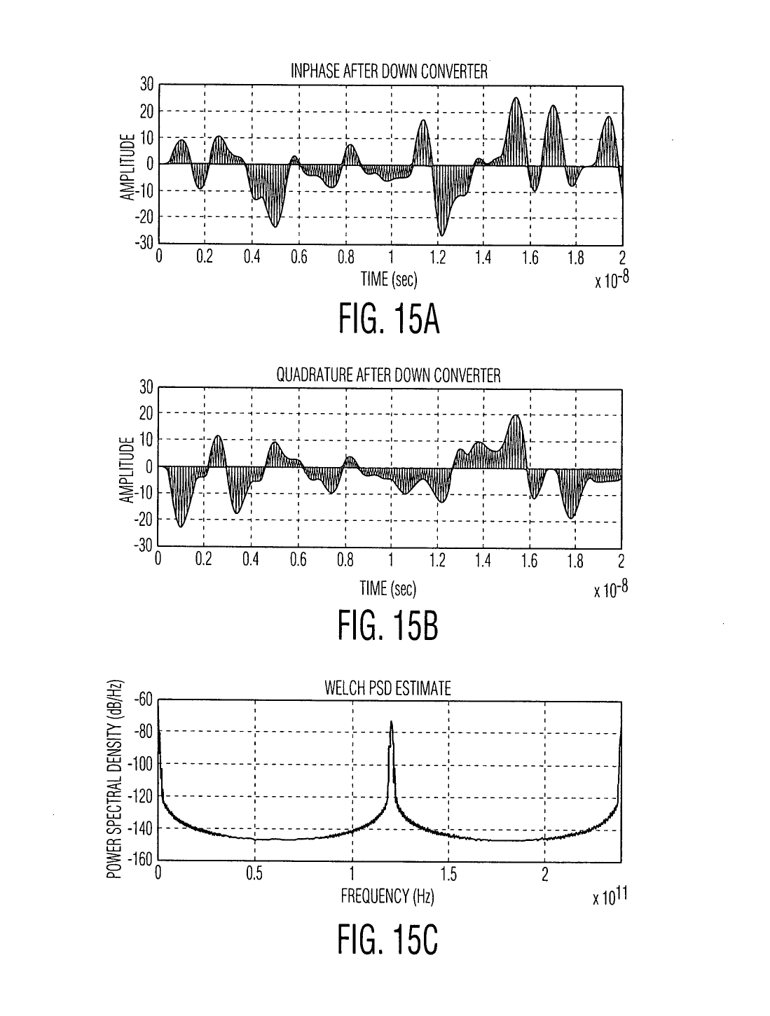

FIGS. 15A-15C, 16A-16C, and 17A-17C correspond to modeled signals in the OFDM/OOK receiver 1000. FIGS. 15A-15B are timing diagrams illustrating in-phase and quadrature components of an OFDM symbol in the OFDM/OOK receiver 1000 modeled at point (f) (i.e., after modulator 1020). Both the in-phase and the quadrature components of the sample of the OFDM symbol are continuous-time signals containing both base-band and an image. The higher frequency components may be observe as contributions by the image.

FIG. 15C is a graph illustrating a frequency response of the OFDM symbol in the OFDM/OOK receiver 1000 modeled at point (f). The image may be observed in the center of the graph due to the down-conversion operation at modulator 1020.

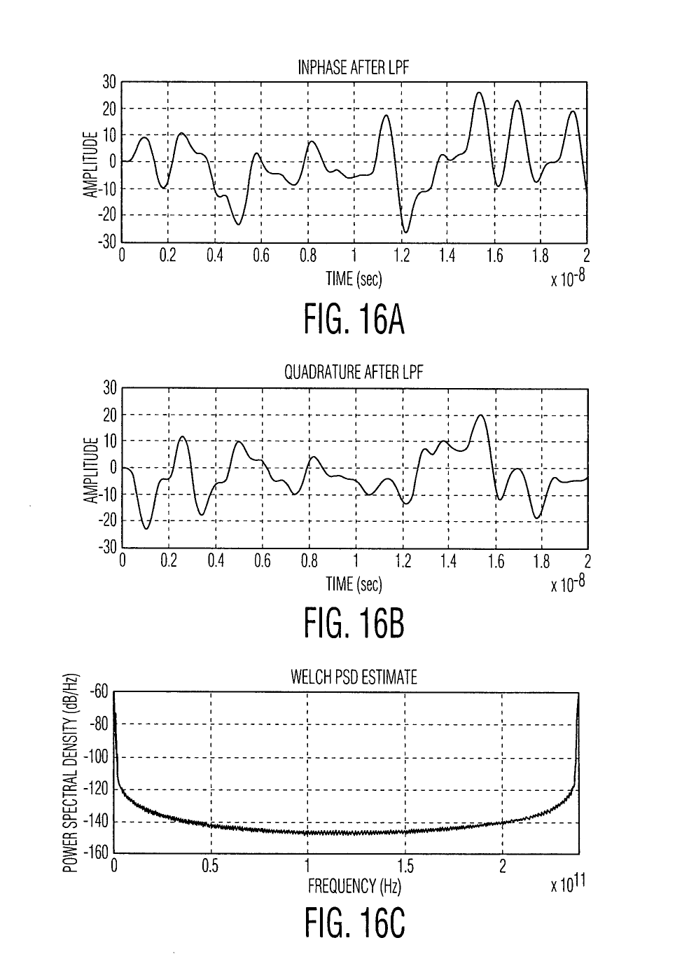

FIGS. 16A and 16B are timing diagrams illustrating in-phase and quadrature components of the OFDM symbol in the OFDM/OOK receiver 1000 modeled at point (g) (i.e., after LPF 1030) of the OFDM/OOK receiver 1000. The in-phase and quadrature components of the samples of the OFDM symbol are both continuous time base-band signals. FIG. 16C a graph illustrating a frequency response of the OFDM symbol in OFDM/OOK receiver 1000 modeled at point (g) (i.e., after the LPF 1030). FIG. 16C is a graph of the frequency response of the OFDM symbol of FIGS. 16A and 16B modeled at point (g). The image may be removed by the LPF 1030.

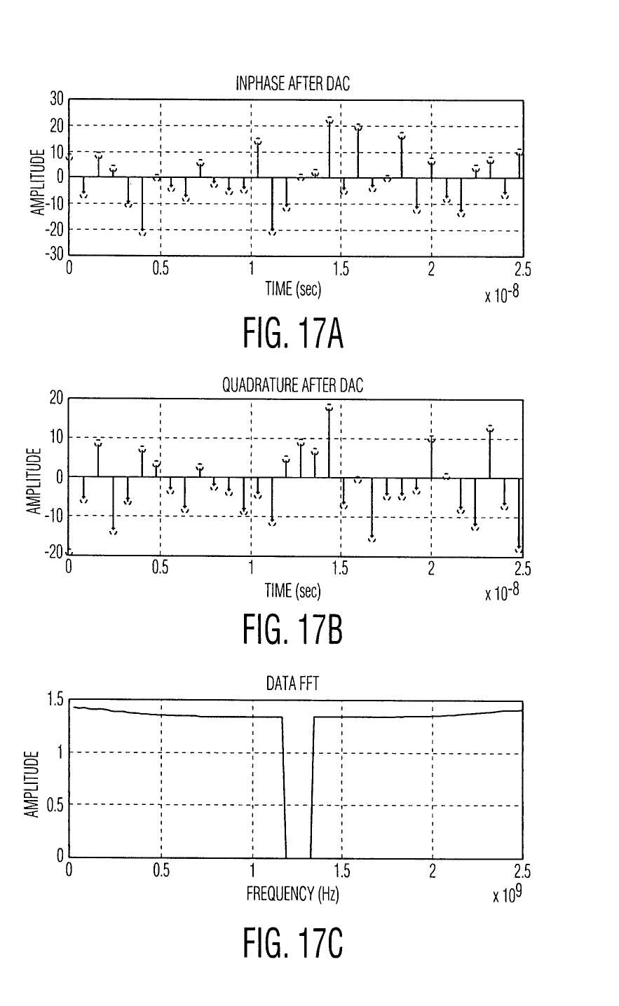

FIGS. 17A-17B are timing diagrams illustrating in-phase and quadrature components of the OFDM symbol in the OFDM/OOK receiver 1000 modeled at point (h) (i.e., after ADC 1040). The in-phase and quadrature components of the samples of the OFDM symbol may be discrete-time base-band signals. FIG. 17C is a graph illustrating a frequency response of the OFDM symbol in the OFDM/OOK receiver 1000 modeled at point (h). The spectrum of the OFDM symbol may be substantially flat over the frequencies with data sub-carriers and may be deeply null over the frequencies with guard sub-carriers. The in-phase and quadrature components of the samples of the OFDM symbol may be provided to the FFT module 1060 via S/P 1050.

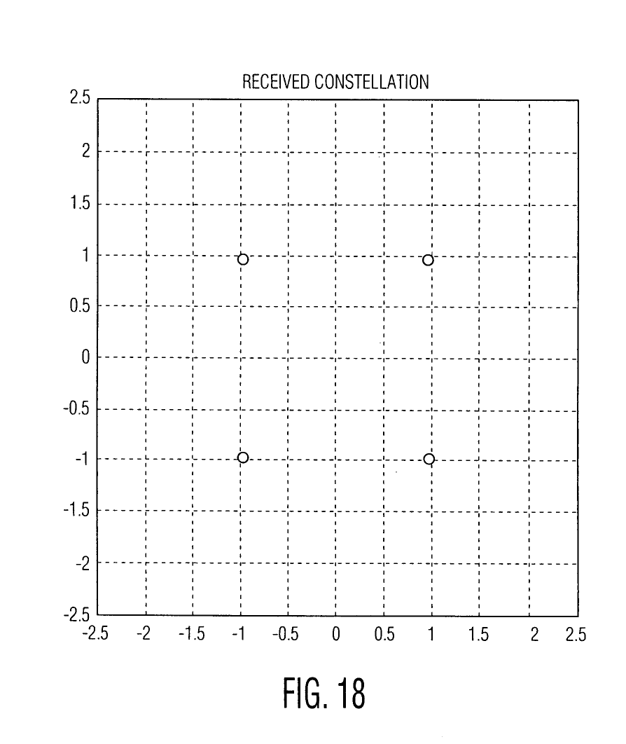

FIG. 18 is a graph illustrating a constellation modeled at point (i) of OFDM/OOK receiver 1000 (i.e., after FFT module 1060). The simulation illustrates a clear QPSK constellation modeled as being received by OFDM/OOK receiver 1000.

The second simulation is a model of an OOK modulated signal being transmitted from an OOK transmitter to an OFDM/OOK receiver. The system parameters used in the simulation include those shown in Table 1 above. For example, the symbol time in the simulation is 800 ps and the symbol rate is 1.25 GHz, the same as the sample rate of an OFDM system.

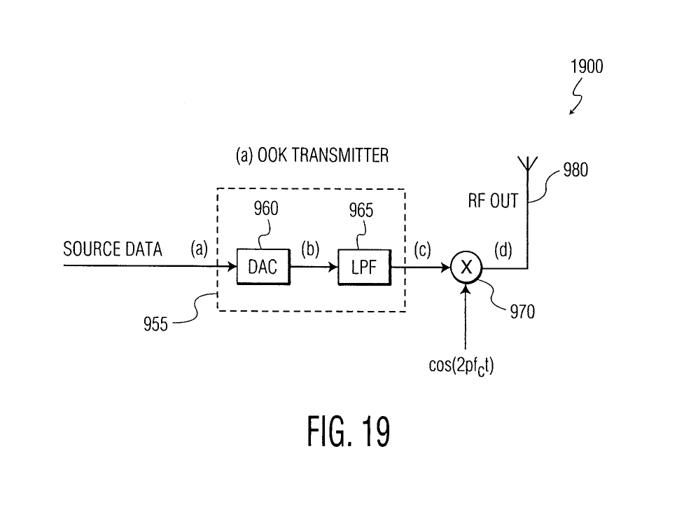

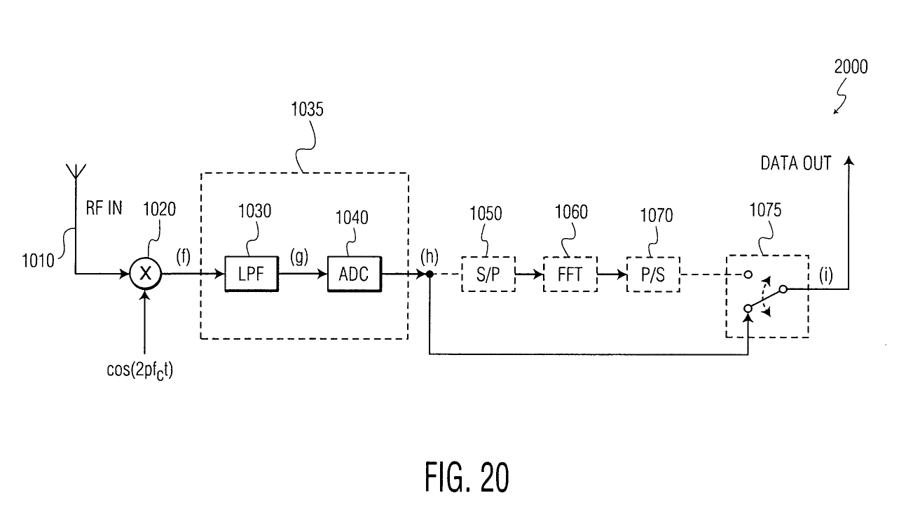

FIG. 19 is a block diagram illustrating an OOK transmitter 1900. FIG. 20 is a block diagram illustrating an OFDM/OOK receiver 2000 in accordance with yet another embodiment of the invention;

The OOK transmitter 1900 operates in the same manner as OFDM/OOK transmitter 900 when the switching unit 910 is in the second position (i.e., in the second mode of operation) such that OFDM/OOK transmitter 900 operates in the OOK modulation mode. The OFDM/OOK receiver 2000 operates in the same manner as OFDM/OOK receiver 1000 when the switching unit 1075 is in the second position (i.e., in the second mode of operation) such that OFDM/OOK receiver 1000 is demodulating an OOK modulated signal. The OOK transmitter 1900 may include a DAC 960 that may generate impulses in continuous-time followed by the LPF 965 filtering the high frequency components of the impulses. The generation of the impulses by DAC 960 and the filtering of the generated impulses at LPF 965 both occur in the signal processor 955 which outputs the filtered version of the impulses.

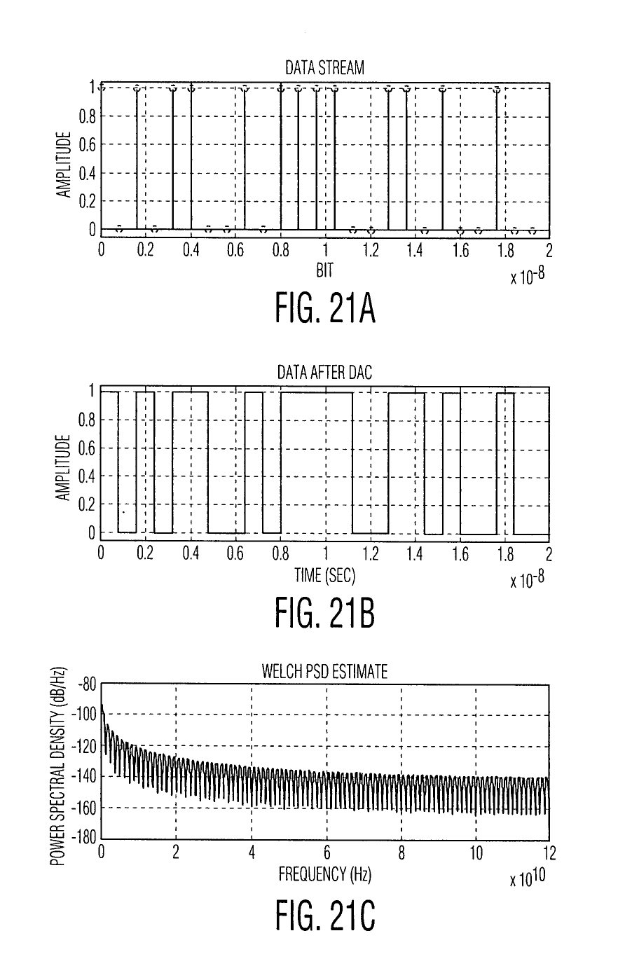

FIGS. 21A-21B are timing diagrams illustrating signals in the OOK transmitter 1900 modeled at points (a) and (b). The source data (e.g., a data stream) that is shown in FIG. 21A may be a discrete-time base-band signal. The data stream may be converted by DAC 960 to an analog signal which may be a continuous-time base-band signal. Since one symbol consists of a single bit, only real signals may be produced by DAC 960. FIG. 21C is a graph illustrating a frequency response of the signal in OOK transmitter 1900 modeled at point (b) (i.e., after DAC 960). Ripples may appear in the stop band. The peak of the stop band ripples may be about −130 d B.

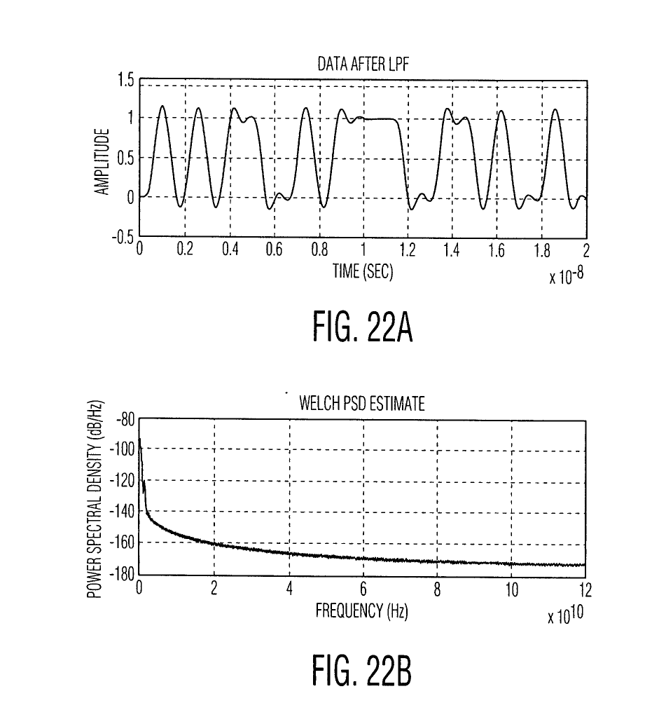

FIG. 22A is a timing diagram illustrating a signal in the OOK transmitter 1900 modeled at point (c) (i.e., after LPF 965). The base-band signal is smoothed, as the high frequency components of the base-band signal with the image are removed by LPF 965. FIG. 22B is a graph illustrating a frequency response of the signal in the OOK transmitter 1900 modeled at point (c). Ripples in the stop band may be removed so that the stop band spectrum may be reduced to below about −160 bB.

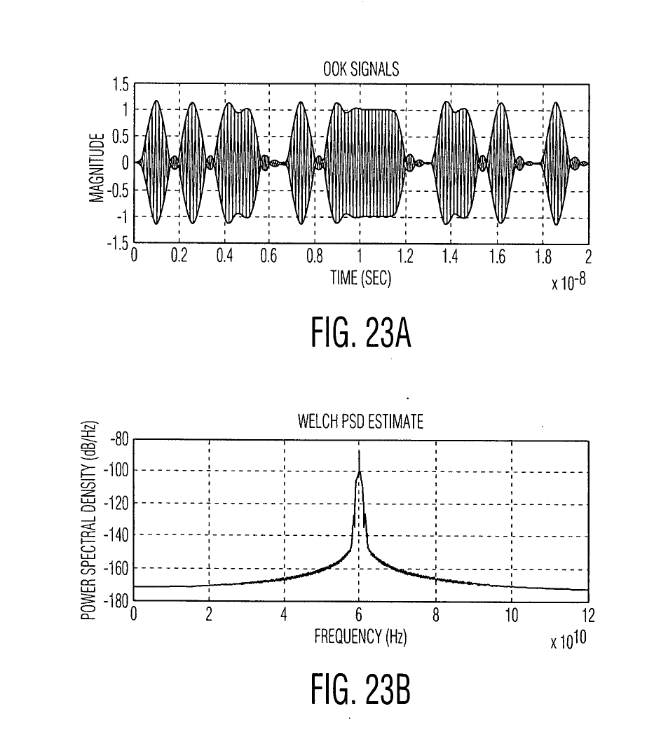

FIG. 23A is a timing diagram illustrating an OOK modulated signal in OOK transmitter 1900 modeled at point (d) (i.e., after modulator 970). The OOK modulated signal is a continuous-time pass-band signal. FIG. 23B is a graph illustrating a frequency response of the OOK modulated signal in OOK transmitter 1900 modeled at point (d). The center frequency is at about 60 GHz.

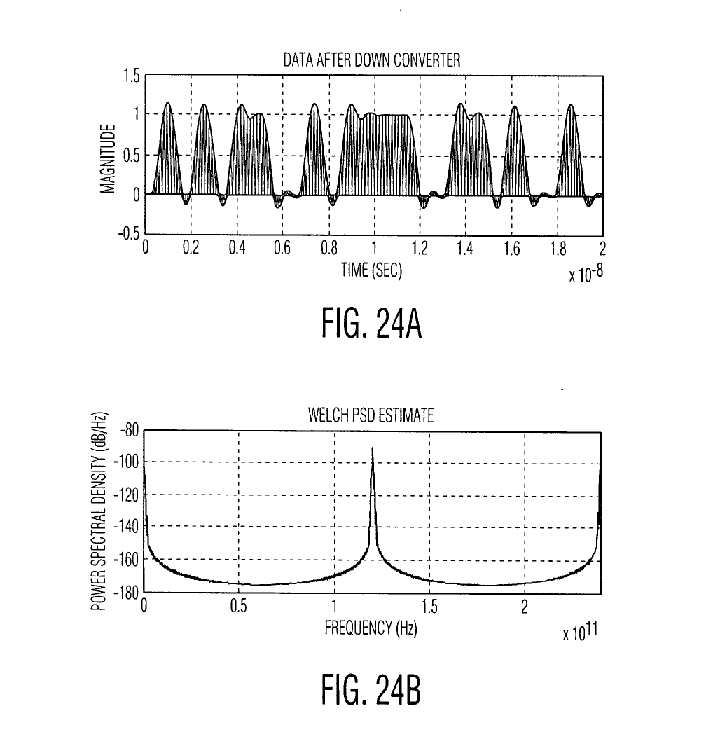

FIG. 24A is a timing diagram illustrating a signal in the OFDM/OOK receiver 2000 modeled at point (f) (i.e., after demodulator 1020). The signal modeled at point (f) is in the time domain and is a continuous time signal containing both the base-band and an image. The higher frequency component may be observed as a contribution by the image. FIG. 24B is a graph illustrating the frequency response in of the signal the OFDM/OOK receiver 2000 modeled at point (f); The image may be observed in the center of the graph and is due to the demodulation operation at demodulator 1020.

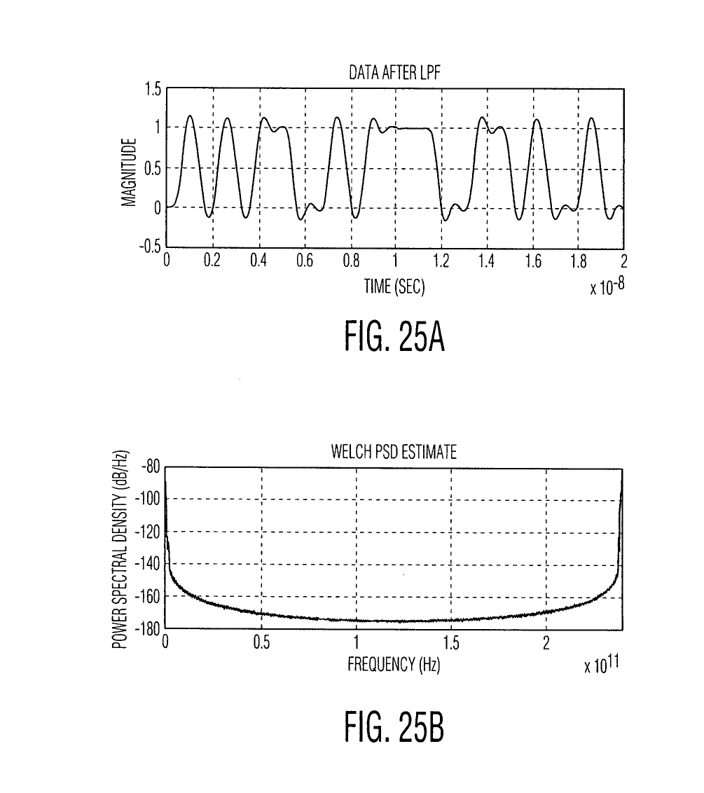

FIG. 25A is a timing diagram illustrating a signal in the OFDM/OOK receiver 2000 modeled at point (g) (i.e. after LPF 1030). The signal is a continuous time base-band signal and is smoothed by removing the high frequency components. FIG. 25B is a graph illustrating a frequency response of the signal in OFDM/OOK receiver 2000 modeled at point (g). The image is removed in the LPF operation by LPF 1030.

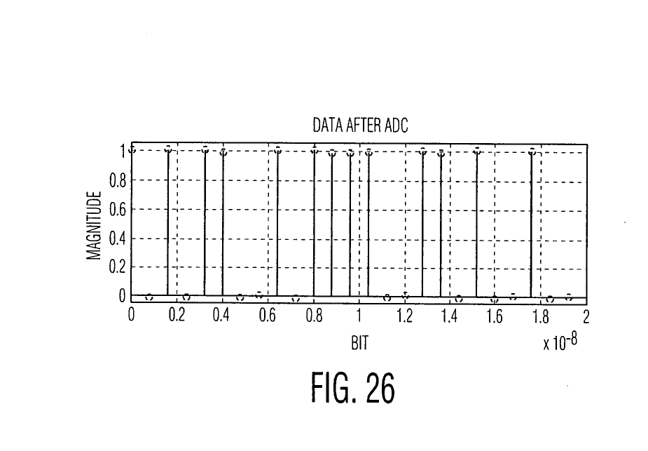

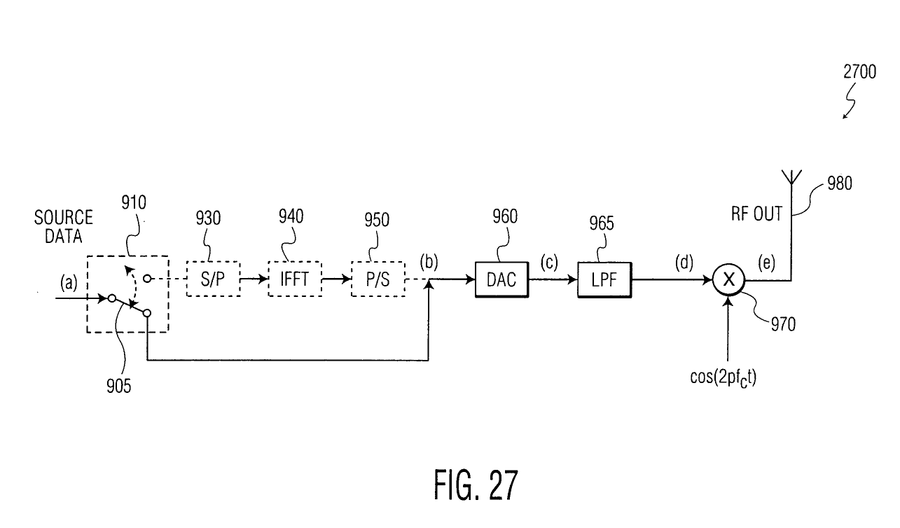

FIG. 26 is a timing diagram illustrating the signal in the OFDM/OOK receiver 2000 modeled at point (h) (i.e., after ADC 1040). This signal is a discrete time base-band signal. FIG. 26 may be compared to the original signal in FIG. 21A. That is, the pattern of the demodulated data is the same as the pattern of the original data from FIG. 21A. Differences in the signal magnitude, however, may be observed. One skilled in the art understands that such differences may be compensated for by either an Automated Gain Control (AGC) or a dynamically adjusted threshold, or both, in the OFDM/OOK receiver. Thus, the differences in the signal magnitude may be considered insignificant.

In the third simulation, the OFDM/OOK transmitter 2700 may be used to transmit an OOK modulated signal to an OOK receiver 2800. The OFDM/OOK transmitter 2700 operates in the same manner as the OFDM/OOK transmitter 900 and may transmit an OOK modulated signal in the second mode of operation. The OOK receiver 2800 operates in a similar manner to that of the OOK receiver 600.

FIG. 27 is a block diagram illustrating an OFDM/OOK transmitter 2700 in accordance with yet another exemplary embodiment of the invention.

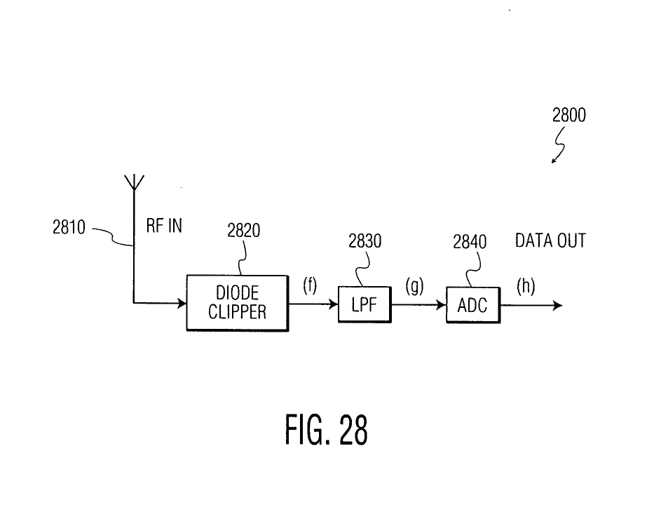

FIG. 28 is a block diagram illustrating an OOK receiver 2800.

Referring now to FIG. 28, OOK receiver 2800 may include an antenna 2810, a diode clipper 2820, an LPF 2830 and an ADC 2840. The OOK receiver 2800 also may include an FEC decoder and a descrambler (not shown). The OOK receiver 2800 may receive the OOK modulated signal, for example, from the OFDM/OOK transmitter 2700. That is, the OFDM/OOK transmitter 2700 may transmit an OOK modulated signal when the switching unit 905 is in the second position (i.e., in the second mode of operation). The diode clipper 2800 may receive the OOK modulated signal via antenna 2810 and may clip the received signal such that only positive values of the signal remain in the output from diode clipper 2820. The LPF 2830, which may be coupled to diode clipper 2820, may receive from diode clipper 2820 the clipped signal and may remove high frequency components of the clipped signal and may output the low frequency components of the clipped signal to ADC 2840. ADC 2840, which is coupled to LPF 2830, may receive the low frequency components of the clipped signal and may output a digital version (a sampled version) of the low frequency components of the clipped signal.

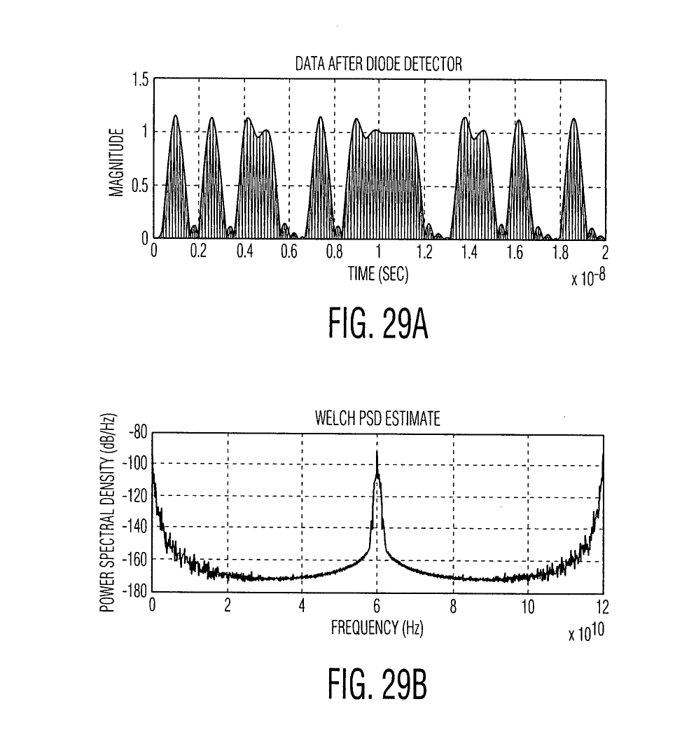

FIG. 29A is a timing diagram illustrating a signal of the OOK receiver 2800 modeled at point (f) (i.e., after diode clipper 2800). This signal is a continuous-time signal in the time domain containing a base-band and an image. High frequency components may be viewed as a contribution by the image. FIG. 29B is a graph illustrating a frequency response of the signal in OOK receiver 2800 modeled at point (f). The image may be observed in the center of the graph due to the clipping operation by diode clipper 2820.

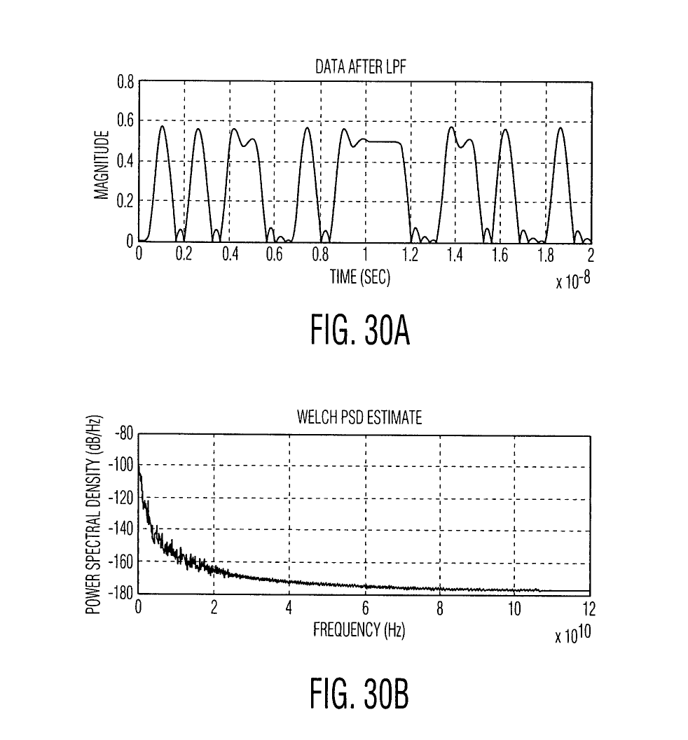

FIG. 30A is a timing diagram illustrating the signal in the OOK receiver 2800 modeled at point (g) (i.e., after LPF 2830). The signal is a continuous-time based-band signal. The signal is smoothed to remove high frequency components. FIG. 30B is a graph illustrating a frequency response of the signal in the OOK receiver 2800 modeled at point (g). The frequency response illustrates that the image may be removed by the LPF operation using LPF 2830.

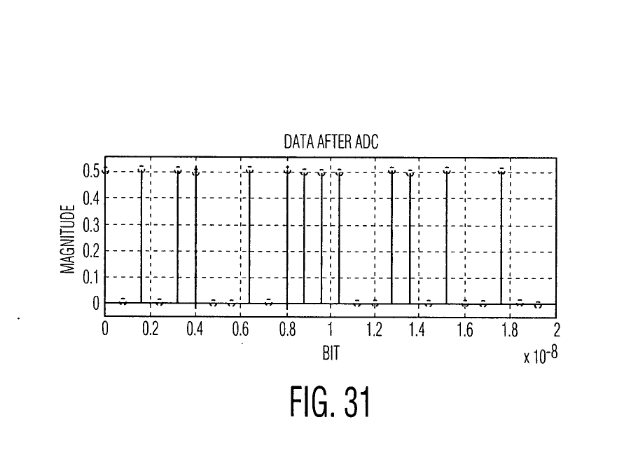

FIG. 31 is a timing diagram illustrating the signal in the OOK receiver 2800 modeled at point (h) (i.e., after ADC 2840). This signal is a discrete-time base-band signal and may be compared with the data stream in FIG. 21A (i.e., in the OOK transmitter 1900 modeled at points (a)). The pattern of the demodulated data in FIG. 31 is the same as the pattern of the data stream in FIG. 21A. Differences in the signal magnitude between the data stream and that of the demodulated data stream are insignificant.

Preambles are used for signal acquisition and time synchronization, among others. Preambles may refer to a sequence of symbols in the time domain. A receiver, including an OFDM receiver, may utilize (stored) a template of the preambles to (i.e., predetermined patterns) perform correlation with an incoming signal to search for a pattern in one or more portions of a received preamble.

An algorithm for searching for a pattern of a preamble is set forth as follows in equation (7):

$${I}_{m} ( l ) = {\sum }_{k = 0}^{K - 1} r ( {t}_{k} + l ) \cdot {p}_{m} ( k ) \qquad ( 7 )$$

where pₘ denotes preamble pattern indexed by m in which k denotes kth waveform in the preamble pattern, r denotes the incoming signal, tₖ denotes the timing of the incoming signal and/denote samples in the incoming signal.

If a preamble pattern is included in the incoming signal, the correlation may produce a maximum value, (i.e., either a positive peak or a negative peak, the amplitude of which is larger than its neighbors). Such that if Iₘ(1) is greater than a predetermined threshold the preamble pattern is determined to be found. Certain sequences of logic level ‘1’ and logic level ‘0’ have good properties of auto correlation and cross correlation so that two systems using different patterns may be easily recognized. Three such patterns include:

$$\text{Pattern} 1 \text{:} 1010101010101010 …$$

$$\text{Pattern} 2 \text{:} 1100110011001100 …$$

$$\text{Pattern} 3 \text{:} 1111000011110000 …$$

### One skilled in the art understands that many other such patterns exists.

Usually in OOK modulated systems, bits are mapped to signal levels given by:

Logic level ‘1’→1

Logic level ‘0’→0

### That is, a logic level ‘1’ may be mapped to a signal level of 1 (i.e., a signal being present) while logic level ‘O’ may be mapped to a zero signal level (i.e., no signal being present).

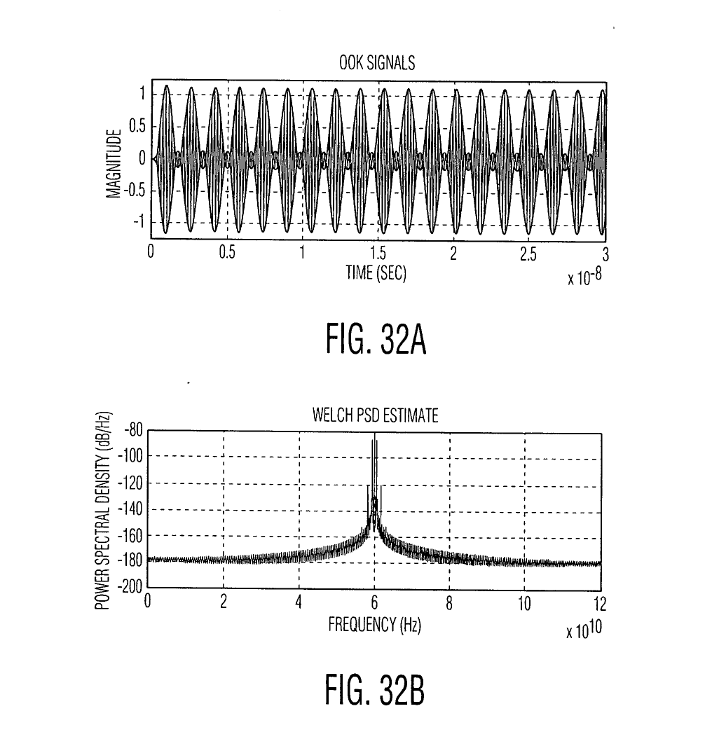

FIGS. 32A and 32B are a timing diagram and a graph illustrating time and frequency responses for a predetermined pattern generated by an OOK transmitter. The logic level ‘1’ in the OOK modulated signal may be depicted by the signal being high in magnitude while logic level ‘0’ may be depicted as the signal being substantially zero in magnitude.

Referring to FIGS. 32A and 32B, a predetermined pattern (i.e., pattern 1) may be input to the OOK transmitter. The resulting frequency response may be modeled and illustrates that a repetition of a fixed pattern (i.e., ‘10’ in pattern 1) may cause a line spectra to be observable. The interval between two line spectra may be 625 MHz for pattern 1.

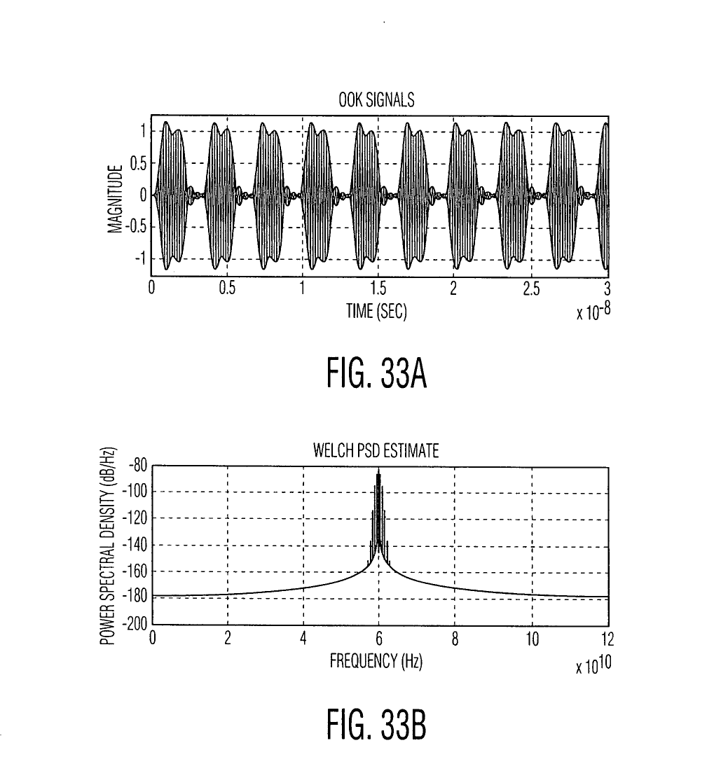

FIGS. 33A and 33B are a timing diagram and a graph illustrating time and frequency responses for another predetermined pattern generated by an OOK transmitter.

Referring to FIGS. 33A and 33B, a different predetermined pattern (i.e., pattern 2) may be input to the OOK transmitter. The resulting frequency response may be modeled and illustrates that a repetition of a fixed pattern (i.e., ‘1100’ in pattern 2) may cause a different line spectra to be observable. The interval between two line spectra may be 312.5 MHz for pattern 2. That is, pattern 2 may have a different interval between two lines (e.g., half that of pattern 1). Thus, different preamble patterns may be determined by an OOK transmitter or OOK receiver.

In an OFDM only system, BPSK may be used for preambles and bits may be mapped to signal levels given by:

Logic level ‘1’→1

Logic level ‘0’→1

### That is, a logic level ‘1’ may be mapped to a first phase (e.g., 0°) and a signal level of 1 and a logic level ‘0’ may be mapped to a second phase (for example, 180°) and a signal level of −1.

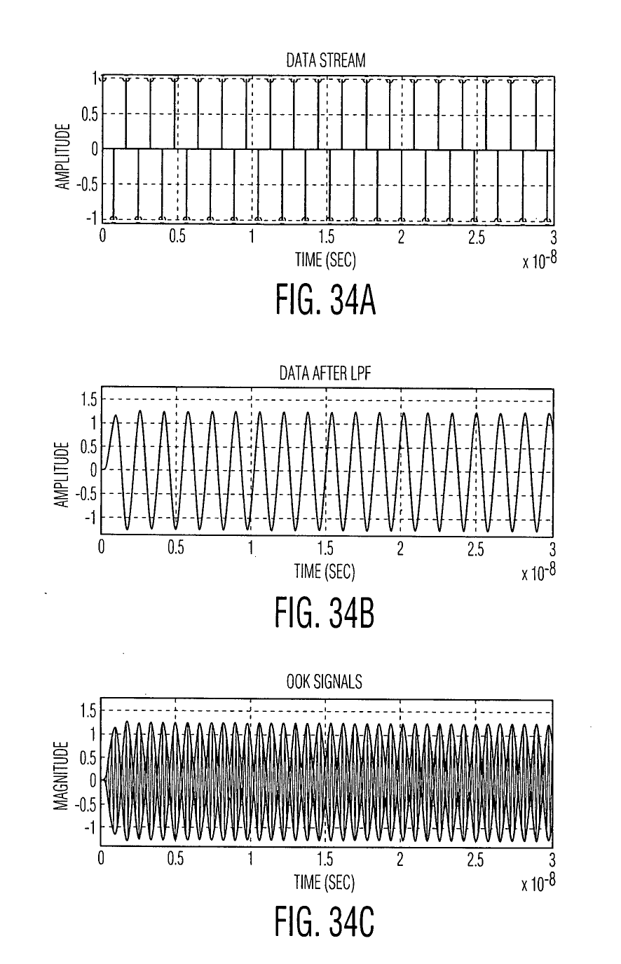

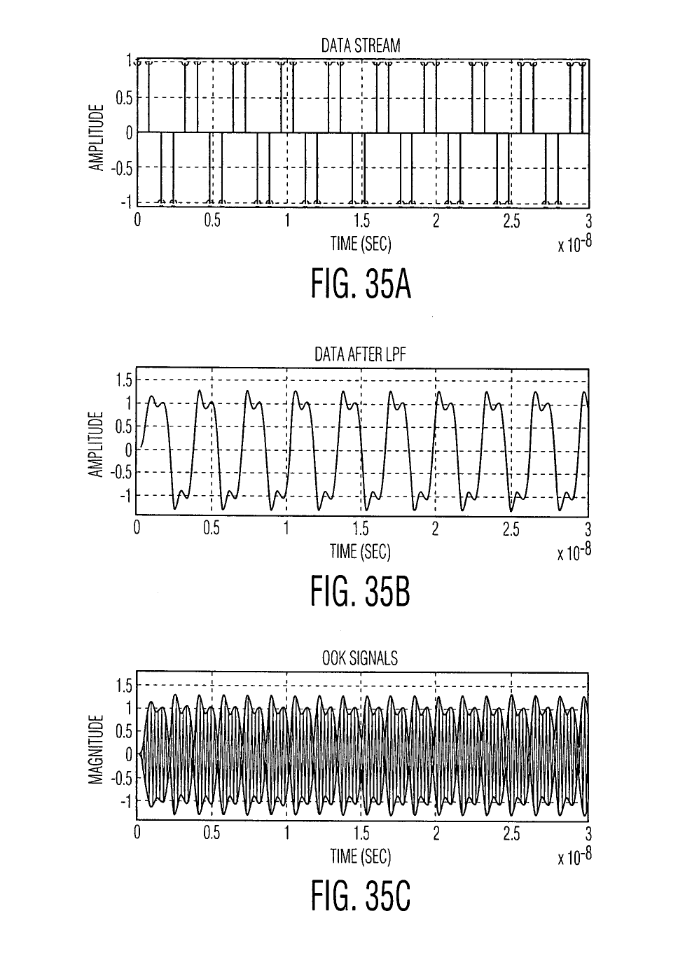

FIG. 34A is a timing diagram illustrating source data (pattern 1) input to OFDM transmitter 700. FIG. 34B is a timing diagram illustrating a signal in the OFDM transmitter 700 modeled at point (d) (i.e., after LPF 765) when the source data (pattern 1) is modulated using Binary Phase Shift Keying (BPSK). FIG. 34C is a timing diagram illustrating the signal in the signal in the OFDM transmitter 700 modeled at point (e) when the source data (pattern 1) is modulated using BPSK.

Now referring to FIGS. 34A-34C, it is observed from FIG. 34B that logic level ‘1’ is mapped to 1 in and logic level ‘0’ is mapped to −1 in the base-band. Both logic level ‘1’ and logic level ‘0’ generate signals in the pass-band, but with different phases. The OFDM receiver 800, for example, uses phase information to perform time synchronization. Typically, the phase information allows for more accurate synchronization. An OOK receiver demodulating the signal illustrated in FIG. 34C may improperly generate a demodulated data stream of all logic level ‘1’ bits. This is because, for example, since there is no appreciable difference between the magnitude of the modulated carrier in FIG. 34C for portions of the signal that represent logic level ‘1’ and logic level ‘0’ in the original pattern (i.e., pattern 1), an OOK receiver may interpret the signal as bits of all the same logic level (i.e., logic level ‘1’ in this case).

FIG. 35A is a timing diagram illustrating source data (pattern 2) input to OFDM transmitter 700. FIG. 35B is a timing diagram illustrating a signal in the OFDM transmitter 700 modeled at point (d) (i.e., after LPF 765) when the source data (pattern 2) is modulated using BPSK. FIG. 35C is a timing diagram illustrating the signal in the signal in the OFDM transmitter 700 modeled at point (e) when the source data (pattern 2) is modulated using BPSK.

Now referring to FIGS. 35A-35C, it is observed from FIG. 35B that logic level ‘1’ is mapped to 1 in and logic level ‘0’ is mapped to −1 in the base-band. Both logic level ‘1’ and logic level ‘0’ generate signals in the pass-band, but with different phases. An OOK receiver demodulating the signal illustrated in FIG. 35C, similar to the results for pattern 1 may improperly generate a demodulated data stream of all logic level ‘1’ bits.

Due to non-coherent detection used by a OOK receiver, the OOK receiver may only detect OOK preambles while an OFDM only receiver may detect both OFDM preambles and OOK preambles.

By setting certain operating rules an OOK only receiver may detect OFDM preambles. The following rules include:

OOK and OFDM systems may use different preamble patterns (e.g., patterns 1, pattern 2 or pattern 3, among others). The OOK modulated signals may use pattern 1 and the OFDM modulated signals may use pattern 2 to identify themselves as OOK modulated signals and OFDM modulated signals, respectively; and

In OFDM systems, bits may be mapped the same as in OOK preambles (i.e.,

Logic level ‘1’→1

Logic level ‘0’→0

With the above mentioned two rules, an OFDM preamble may be detected by an OOK only receiver. However, because the number of pulses reduces by half, (due to the above-mentioned mapping of Logic level ‘0’ to signal level 0) the results of time synchronization for OFDM systems may be degraded. To maintain performance for time synchronization, another bit mapping may be used for an OFDM preamble, namely:

Logic level ‘1’→2

Logic level ‘0’→1

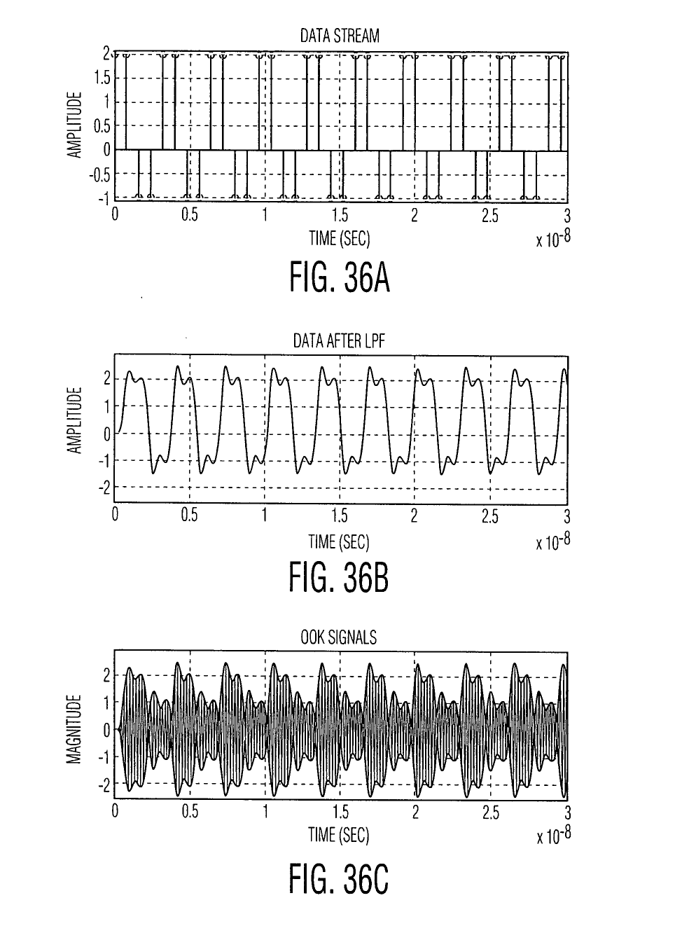

FIG. 36A is a timing diagram illustrating the use of an unbalanced DC mapping according to yet another exemplary embodiment of the invention. FIG. 36B is a timing diagram illustrating a signal in the OFDM transmitter 700 modeled at point (d) when the source data (pattern 2) of FIG. 36A is modulated using BPSK. FIG. 36C is a timing diagram illustrating the signal in the OFDM transmitter 700 modeled at point (e) when the source data (pattern 2) of FIG. 36A is modulated using BPSK;

Now referring to FIGS. 36A-36C, with an unbalanced mapping (e.g., pattern 2 with the bit mapping of logic level ‘1’ to a signal level of 2 and logic level ‘0’ mapped to a signal level of −1), an OOK only receiver may employ different levels of bits in the preamble to perform non-coherent detection and an OFDM receiver may use phase information of the bits in the preamble to perform coherent detection. For example, since there is a difference between the magnitude (signal level) of the modulated carrier in FIG. 36C for portions of the signal that represent logic level ‘1’ and logic level ‘0’ (i.e., the absolute value of the signal level for portions of the signal in FIG. 36C representing logic level ‘1’ is substantially 2 while the absolute value of the signal level for portions of the signal in FIG. 36C representing logic level ‘0’ is substantially 1), an OOK receiver may interpret the signal properly.

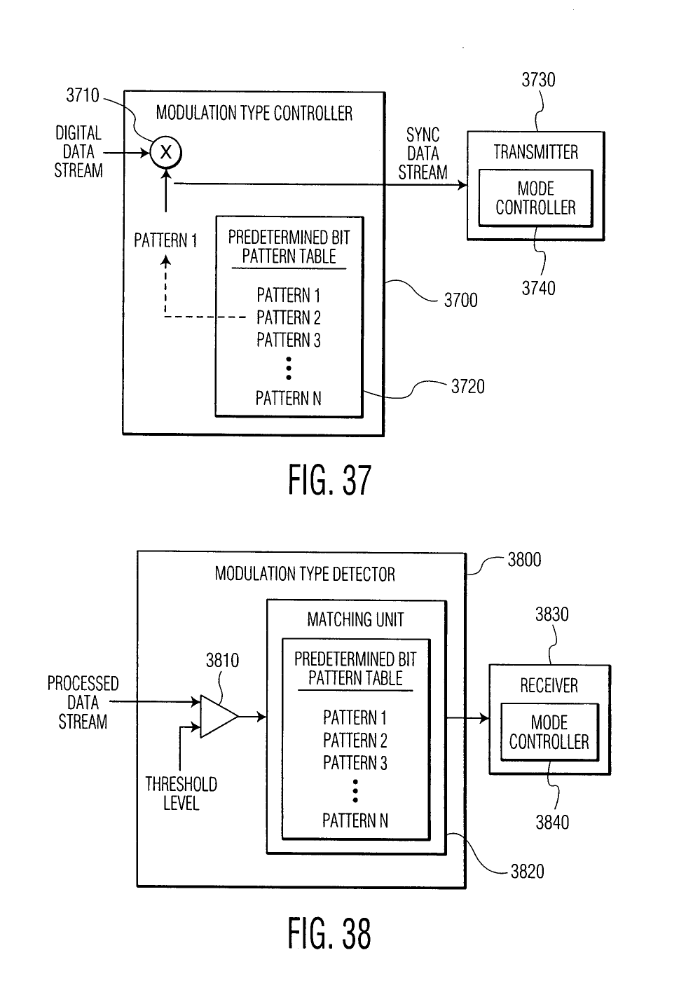

FIG. 37 is a block diagram illustrating a modulation type controller in accordance with yet another exemplary embodiment of the invention.

Referring to FIG. 37, the modulation type controller 3700 may include a multiplexer 3710 for inserting a predetermined bit pattern into a digital data stream to form a sync data stream. The predetermined pattern at least indicates a type of modulation used to modulate the digital data stream. For example, the sequence of bits in the predetermined bit pattern may be pattern 1, pattern 2 or pattern 3 shown above and may indicate an OOK modulation type or a OFDM modulation type.

When a particular modulation type is selected, a corresponding predetermined bit pattern from table 3720 may be inserted into the digital data stream. A modulation type signal (not shown) may be sent from the modulation type controller 3700 to the mode controller 3740 to control the mode of operation of the transmitter 3730 (e.g., the OFDM/OOK transmitter). Further, the sync data stream may be demodulated and the predetermined bit pattern may be used to set the mode of the mode control 3840 for a receiver 3830 (as shown in FIG. 38) (e.g., the OFDM/OOK receiver) receiving a modulated version of the sync data stream (i.e., either modulated with an OFDM modulation scheme or an OOK modulation scheme). Thus, the receiver 3830 may be set to enable inverse operations to properly recover the original digital data stream transmitted by the transmitter 3730.

FIG. 38 is a block diagram illustrating a modulation type detector in accordance with yet another exemplary embodiment of the invention.

Referring to FIG. 38, the modulation type detector 3800 may include a threshold detector 3810 for determining a sequence of bits in a bit pattern and a matching unit 3820 for storing the sequence of bits in the bit pattern and for matching the sequence of bits to a predetermined bit pattern. The matching of the sequence of bits to the predetermined bit pattern may be by any known correlation process. A modulation type signal may be sent to the mode controller 3840 of the receiver 3830 to set the mode of the receiver 3830, for example, an OFDM/OOK receiver. By detecting the modulation type and properly setting the mode of operation of the receiver, the original digital data stream may be recovered by receiver 3830.

Although the modulation type controller and modulation type detector are illustrated as separate devices from the transmitter and receiver, it is contemplated that they may be included in the transmitter and receiver. In such a situation, the modulation type controller may be incorporated into the mode controller of the transmitter and the modulation type detector may be incorporated into the mode controller of the receiver 3830. It is also contemplated that the transmitter and receiver may be incorporated into a transceiver, the modulation type controller and in such a case, the modulation type detector and the mode controllers may be incorporated into a single controller to perform the various control functions.

It is contemplated, that the interval of OOK modulated signals may be changed by changing the hold time, for example, of the DAC in an OOK transmitter or OFDM/OOK transmitter. For example, the hold time may be reduced from a full interval of a sample (i.e., t_{DAC}=t_{symbol}) to half of the sample interval, (i.e., the duty cycle may then be 50%, which may be expressed as t_{DAC}=½t_{symbol}) The OOK modulated signal, thus, has a different pulse shape.

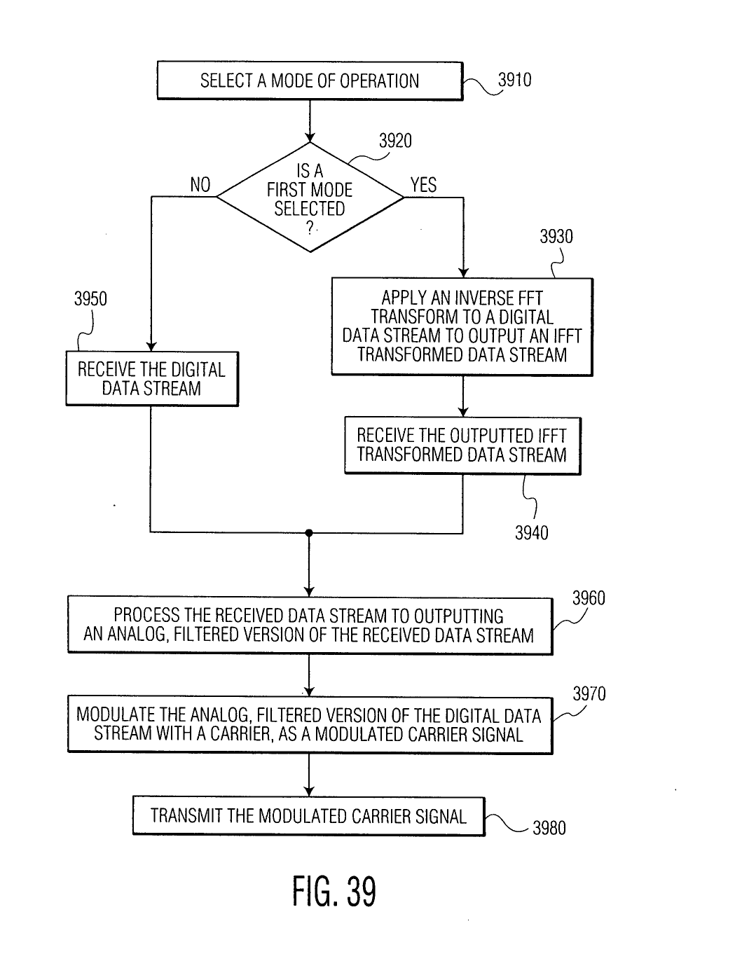

FIG. 39 is a flow chart illustrating a method of processing a digital data stream in accordance with yet another exemplary embodiment of the invention.

Referring to FIG. 39, at block 3910, a mode of operation is selected. The selection of the mode of operation may include selection by a user of the mode of operation or may be controlled via a mode controller 910. In the case of automatic selection via controller 910, the selection may be in accordance with signals detected via a receiver. Moreover, in a transceiver including both a transmitter and a receiver, a single controller may be used to control switching units 905 and 1080.

At block 3920, it is determined if the first mode is selected. At block 3930, if a first mode of operation is selected, an inverse FFT transform is applied to the digital data stream to output an IFFT transformed data stream. At block 3940, the outputted IFFT transformed data stream is received, for example, by signal processor 955 of OFDM/OOK transmitter 900. At block 3950, if, however, the first mode of an operation is not selected (e.g., the second mode of operation is selected), the digital data stream is received by signal processor 955 of OFDM/OOK transmitter 900. At block 3960, the received data stream (e.g., either the outputted IFFT transformed data stream corresponding to the first mode selected or the digital data stream corresponding to the second mode selected is processed to output an analog, filtered version of the received data stream. At block 3970, the analog, filtered version of the digital data stream is modulated with a carrier, as a modulated carrier signal. At block 3980, the modulated carrier signal is transmitted via antenna 980.

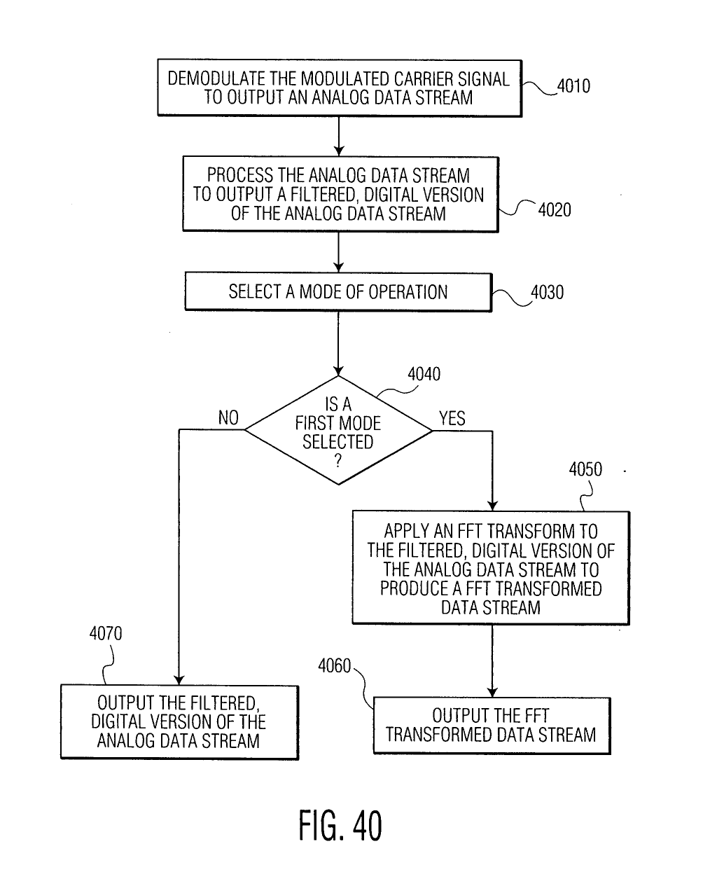

FIG. 40 is a flow chart illustrating a method of processing a modulated carrier signal in accordance with yet another exemplary embodiment of the invention.

Referring to FIG. 40, at block 4010, a modulated carrier signal is demodulated to output an analog data stream. At block 4020, the analog data stream is processed to output a filtered, digital version of the analog data stream. At block 4030, a mode of operation is selected. The selection of a mode of operation: (1) may include the user selecting of the mode of operation; (2) may be in accordance with information in the preamble of the data stream modulated with the carrier signal received by a receiver; and/or (3) may be controlled by a source external to the OFDM/OOK receiver 1000. That is, for example, the preamble of the data stream modulated with the modulated carrier signal transmitted by an OFDM/OOK transmitter 900, may include a unique preamble pattern, for OFDM modulated signals and another unique preamble pattern, for example, for OOK modulated signals. Selection of the mode of operation may be based on detection of a particular preamble pattern. Selection may further include switching of switching unit 1080 in accordance with the detected, unique preamble pattern. That is, a first preamble pattern may be detected by OFDM/OOK receiver 1000 and may indicate an OFDM modulation signal such that switching unit 1080 may be switched to a first position in which FFT module 1060 is in-line with signal processor 1035.

Alternatively, OFDM/OOK receiver 1000 may detect a second preamble pattern that indicates an OOK modulated signal such that switching unit 1080 switches to a second position in which FFT module 1060 is bypassed. The determination of the logical levels of the preamble pattern may be based of a comparison of the absolute value of the magnitude of the modulated signal level to a threshold value. In such a case, the logical levels may be mapped to unbalance signal levels.

In certain exemplary embodiments of the invention OFDM/OOK transmitters are shown, in other exemplary embodiments of the present invention, OFDM/OOK receivers are shown. It is contemplated, that OFDM/OOK receivers and transmitters may be combined to provide an OFDM/OOK transceiver. In such a transceiver, it is contemplated that bi-directional communication between a particular device having the OFDM/OOK transceiver and another device may occur. In such a situation, it is contemplated that the OFDM/OOK receiver and OFDM/OOK transmitter may be controlled by a single mode controller, such that switching units of OFDM/OOK transmitter and receiver may be controlled based on the preamble detected by the OFDM/OOK receiver. When the OFDM/OOK receiver detects, for example, that an OOK modulated signal is being received, one or both of the OFDM/OOK transmitter and OFDM/OOK receiver may automatically select the OOK mode of operation (i.e., to transmit and/or receive using OOK modulated signal processing). When the OFDM/OOK receiver detects, for example, that an OFDM modulated signal is being received, one or both of the OFDM/OOK transmitter and the OFDM/OOK receiver may automatically select the OFDM mode of operation (i.e., to transmit and/or receive using OFDM modulated signal processing).

At block 4040, it is determined whether a first mode is selected. At block 4050, if the first mode is selected, then an FFT transform is applied to the filtered, digital version of the analog data stream to produce an FFT transformed data stream. At block 4060, the FFT transformed data stream is outputted. At block 4070, however, if the first mode is not selected, the filtered, digital version of the analog data stream is outputted. That is, if the first mode is selected (corresponding to the OFDM modulated signal), then the FFT transformed data stream is outputted. Moreover, if a second mode of operation is selected (corresponding to, for example, the OOK modulated signal), then the filtered, digital version of the analog data stream is outputted.

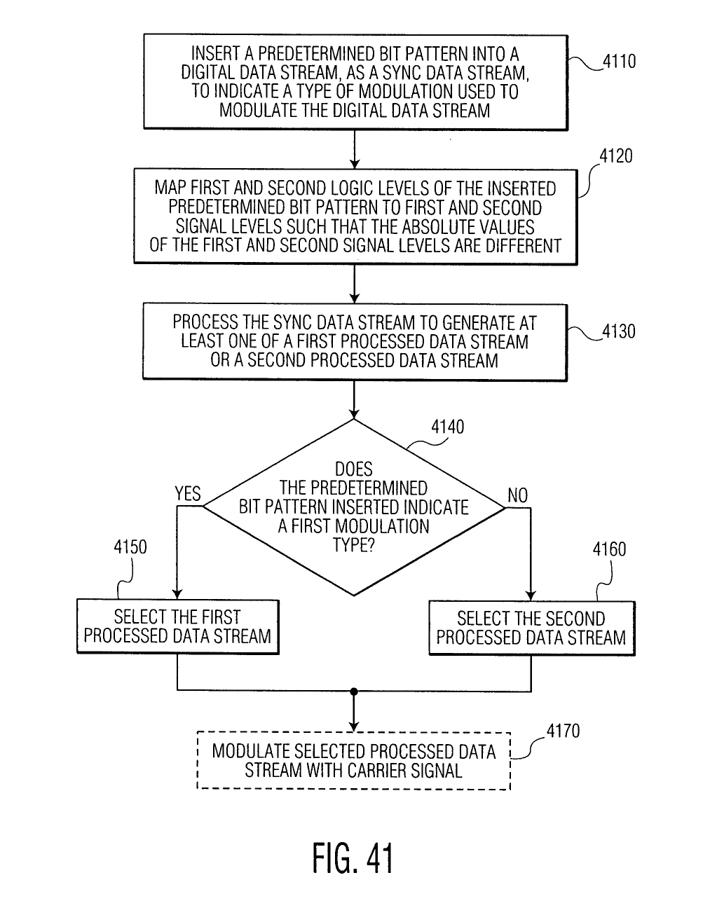

FIG. 41 is a flow chart illustrating a method of processing a digital data stream in accordance with yet another exemplary embodiment of the invention.

Referring to FIG. 41, at block 4110, a predetermined bit pattern may be inserted into the digital data stream to form the sync data stream. The sync data stream may indicate a type of modulation used to modulate the digital data stream. At block 4120, first and second logic levels of the predetermined bit pattern may be mapped to first and second signal levels such that absolute values of the first and second signal levels are different. At block 4130, the sync data stream may be processed to generate at least one of a first processed data stream or a second processed data stream. The first processed data stream may be in accordance with a first modulation type (e.g., OFDM modulation) and the second processed data stream may be in accordance with a second modulation type (e.g., OOK modulation).

At block 4140, it may be determined whether the inserted bit pattern indicates the first modulation type. At block 4150, if the inserted bit pattern indicates the first modulation type, the first processed data stream may be selected. At block 4160, if, however, the inserted bit pattern does not indicate the first modulation type (e.g., it indicates the second modulation type), the second processed data stream may be selected. At block 4170, the selected processed data stream may be modulated and may be transmitted.

Although the decision step at block 4140 is illustrated after other steps (i.e., the insertion, mapping and processing steps, it is contemplated that the order of these steps may be changed.

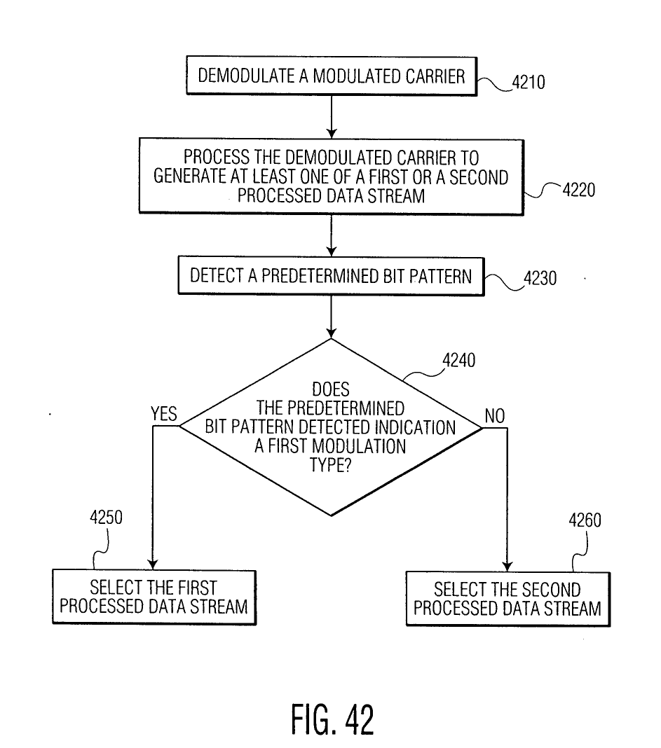

FIG. 42 is a flow chart illustrating a method of processing a modulated carrier signal in accordance with yet another exemplary embodiment of the invention.

Referring to FIG. 42, at block 4210, the modulated carrier may be demodulated. At block 4220, the modulated carrier may be processed to generate at least one of a first processed data stream or a second processed data stream. The first data stream may be processed according to a first type of modulation and the second data stream may be processed according to a second type of modulation.

At block 4230, a predetermined bit pattern in at least one of the first processed data stream or the second processed data stream may be detected regardless of whether the predetermined bit pattern had been modulated using the first or the second modulation type. A sequence of bits in the predetermined bit pattern may at least indicate the respective modulation type that had been used to modulate the predetermined bit pattern.

At block 4240, it may be determined whether the detected predetermined bit pattern indicates the first modulation type. At block 4250, if the detected predetermined bit pattern indicates the first modulation type, the first processed data stream may be selected. At block 4260, if, however, the detected predetermined bit pattern does not indicate the first modulation type (e.g., it indicates the second modulation type), the second processed data stream may be selected.

Although the invention has been described in terms of a method and apparatus for communication using different modulation schemes, it is contemplated that it may be implemented in software on microprocessors/general purpose computers (not shown). In various embodiments, one or more of the functions of the various components may be implemented in software that controls a general purpose computer. This software may be embodied in a computer readable carrier, for example, a magnetic or optical disk, a memory-card or an audio frequency, radio-frequency, or optical carrier.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A transmitter receiving a digital data stream for transmission thereof, comprising:
a transformation module for applying an inverse FFT transform to the digital data stream and outputting an IFFT transformed data stream;
a mode switch for selecting one of a first mode or a second mode;
a signal processor, receiving one of the digital data stream or the outputted IFFT transformed data stream according to the selected mode, processing the received data stream and outputting an analog, filtered version of the received data stream; and
a modulator receiving the outputted analog, filtered version of the received data stream and modulating the analog, filtered version of the digital data stream with a carrier, as a modulated carrier signal.

2. The transmitter of claim 1, further comprising:
at least one antenna coupled to the modulator for transmitting the modulated carrier signal.

3. The transmitter of claim 1, wherein the modulated carrier signal is modulated using one of: (1) an on/off keying or (2) an orthogonal frequency division multiplexing (OFDM) modulation scheme.

4. The transmitter of claim 1, further comprising:
a mode controller for detecting predetermined sequences of bits in the digital data stream and for controlling the mode switch according to a respective one of the predetermined sequences of bits detected.

5. The transmitter of claim 1, further comprising:
a receiver for receiving a modulated signal, the receiver controlling the selection of the first or second mode.

6. The transmitter of claim 5, wherein the receiver includes a mode controller for detecting predetermined sequences of bits modulated in the received, modulated signal, and for controlling the mode switch according to a respective one of the predetermined sequences of bits detected.

7. The transmitter of claim 1, wherein the selection of the first or second mode is based on one of: (1) an input from a source external to the transmitter; or (2) an input from a user.

8. The transmitter of claim 1, wherein the mode switch is configured to place the transformation module in-line with the signal processor such that the modulated carrier signal is based on the outputted IFFT transformed data stream, responsive to selection of the first mode and the mode switch is configured to bypass the transformation module, responsive to selection of the second mode.

9. A transmitter receiving a digital data stream for transmission thereof, comprising:
a sync unit for inserting a predetermined bit pattern into the digital data stream to form a sync data stream, logic levels of the predetermined bit pattern being mapped to first and second signal levels such that the absolute values of the first and second signal levels are different, the predetermined bit pattern at least indicating a type of modulation used to modulate the digital data stream;
a processing unit for processing the sync data stream to generate at least one of a first processed data stream or a second processed data stream; and
a modulator for receiving at least one of the first processed data stream or second processed data stream and modulating one of the first processed data stream or the second processed data stream with a carrier, as a modulated carrier signal, wherein
the first processed data stream or the second processed data stream is selected for modulation with the carrier in accordance with the type of modulation indicated by the inserted, predetermined bit pattern.

10. A receiver for processing a modulated carrier, comprising:
a demodulator receiving the modulated carrier, demodulating the modulated carrier and outputting an analog data stream;
a signal processor processing the analog data stream and outputting a filtered, digital version of the analog data stream;
a transformation module for applying an FFT transform to the filtered, digital data version of the analog data stream to generate an FFT transformed data stream; and
a mode controller for selecting one of a first mode or a second mode, wherein the receiver outputs one of the filtered, digital version of the analog data stream or the FFT transformed data stream according to the selected mode, as a digital data stream.

11. The receiver of claim 10, further comprising:
at least one antenna coupled to the demodulator for receiving the modulated carrier.

12. The receiver of claim 10, wherein the modulated carrier is modulated using one of: (1) an on/off keying or (2) an orthogonal frequency division multiplexing (OFDM) modulation scheme.

13. The receiver of claim 10, wherein:
the mode controller includes a mode switch configured to place the transformation module in-line with the signal processor such that the output of the receiver is based on the filtered, digital version of the analog data stream responsive to the selection of the first mode and configured to bypass the transformation module, responsive to the selection of the second mode; and
the mode controller detects a predetermined sequences of bits using the digital data stream and controls the mode switch according to a respective one of the predetermined sequences of bits detected.

14. The receiver of claim 13, further comprising:
a transmitter for transmitting modulated signals, the receiver configured to control a type of modulation of the transmitter according to the respective one of the predetermined sequences of bits detected by the mode controller.

15. The receiver of claim 10, wherein the selection of the first or second mode is selected by a user.

16. A receiver for processing a modulated carrier, comprising:
a demodulator for demodulating the modulated carrier;
a processing unit for processing the modulated carrier to generate at least one of a first processed data stream or a second processed data stream, the first data stream to be processed by the processing unit according to a first type of modulation and the second data stream to be processed by the processing unit according to a second type of modulation;
a modulation type detector for detecting predetermined bit patterns in the at least one first or second processed data stream regardless of whether the predetermined bit patterns had been modulated using the first type of modulation or the second type of modulation, the sequence of bits in each predetermined bit pattern at least indicating a respective type of modulation that had been used to modulate the predetermined bit pattern; and
a mode controller for selecting the first processed data stream or the second processed data stream in accordance with a respective predetermined bit pattern detected by the modulation type detector.

17. The receiver of claim 16, wherein first and second signal levels corresponding to binary logic levels of the predetermined bit pattern are selected such that the absolute values of the first and second signal levels are different.

18. A method of processing a digital data stream, comprising:
applying an inverse FFT transform to the digital data stream to output an IFFT transformed data stream;
selecting one of a first mode or a second mode;
receiving one of the digital data stream or the outputted IFFT transformed data stream according to the selected mode;
processing the received data stream to output an analog, filtered version of the received data stream;
modulating the analog, filtered version of the digital data stream with a carrier, as a modulated carrier signal; and
transmitting the modulated carrier signal.

19. The method of claim 18, wherein the step of selecting one of the first mode or the second mode includes:
detecting predetermined sequences of bits in the digital data stream; and
controlling a mode switch according to a respective one of the predetermined sequences of bits detected to place a transformation module in-line with the signal processor such that the modulated carrier signal is based on the outputted IFFT transformed data stream, responsive to the selection of the first mode, and to bypass the transformation module, responsive to the selection of second mode.

20. A method of processing a digital data stream for transmission thereof, comprising the steps of:
inserting a predetermined bit pattern into the digital data stream to form the sync data stream to at least indicate a type of modulation used to modulate the digital data stream;
mapping the first and second logic levels of at least the predetermined bit pattern inserted into the sync data stream to first and second signal levels such that the absolute values of the first and second signal levels are different;
processing the sync data stream to generate at least one of a first processed data stream or a second processed data stream; and
selecting for modulation with a carrier one of the first or second processed data stream in accordance with the type of modulation indicated by the predetermined bit pattern.

21. The method of claim 20, further comprising the steps of:
modulating the selected one of the first or second processed data stream with a carrier, as a modulated carrier; and
transmitting the modulated carrier.

22. A method of processing a received modulated carrier, comprising:
demodulating the received modulated carrier to output an analog data stream;
processing the analog data stream to output a filtered, digital version thereof;
applying an FFT transform to the filtered, digital version to produce an FFT transformed data stream;
selecting one of a first mode or a second mode; and
outputting one of the filtered digital version or the FFT transformed data stream according to the selected mode, as a digital data stream.

23. The method of claim 22, wherein the step of selecting one of the first mode or the second mode includes:
detecting a predetermined sequences of bits using the digital data stream; and
controlling a mode switch according to a respective one of the predetermined sequences of bits detected.

24. The method of claim 23, wherein the step of controlling the mode switch includes the steps of:
placing a transformation module in-line with a signal processor such that the digital data stream is based on the filtered, digital version responsive to the selection of the first mode; and
bypassing the transformation module, responsive to the selection of the second mode.

25. A method of processing a modulated carrier, comprising the steps of:
demodulating the modulated carrier;
processing the modulated carrier to generate at least one of a first processed data stream or a second processed data stream, the first data stream to be processed according to a first type of modulation and the second data stream to be processed according to a second type of modulation;
detecting a predetermined bit pattern in the at least one of the first processed data stream or the second processed data stream regardless of whether the predetermined bit pattern had been modulated using the first or the second modulation type, a sequence of bits in the predetermined bit pattern at least indicating the respective modulation type that had been used to modulate the predetermined bit pattern; and
selecting the first or second processed data stream in accordance the detected predetermined bit pattern.

26. The method of claim 25, wherein the step of detecting the predetermined bit pattern includes the steps of:
determining a sequence of bits in the at least one of the first processed data stream or the second processed data stream by mapping absolute values of first and second signal levels of the at least one first or second processed data stream to binary logic levels, the absolute values of the first and second signal levels being different; and
determining if a portion of the sequence of bits matches the predetermined bit pattern for detection thereof.

27. The method of claim 26, wherein the step of detecting the predetermined bit pattern further includes the steps of:
establishing a threshold value;
responsive to an absolute value of a signal level of the first or second processed data stream being greater than the threshold value, mapping the signal level to a first binary logic level; and
responsive to the absolute value of the signal level of the first or second processed data stream being at or less than the threshold value, mapping the signal level to a second binary logic level.

28. A physical carrier for storing program code executable of a computer to implement the method according to claim 18.

29. A physical carrier for storing program code executable of a computer to implement the method according to claim 22.
